(19) United States
(12) Patent Application Publication
(10) Pub. No.: US 2008/0047743 A1
(43) Pub. Date: Feb. 28, 2008

(54) Multilayer Substrate With Built-In Capacitors, Method For Manufacturing The Same, And Cold-Cathode Tube Lighting Device

(76) Inventors: Akeyuki Komatsu, Ehime (JP); Eiji Miyake, Ehime (JP); Kenji Kawataka, Ehime (JP); Toshio Manabe, Ehime (JP)

Correspondence Address: WENDEROTH, LIND & PONACK L.L.P., 2033 K. STREET, NW, SUITE 800, WASHINGTON, DC, 20006, US

(21) Appl. No.: 11/667,932

(22) PCT Filed: Nov. 16, 2005
(86) PCT No.: PCT/JP05/21042

§ 371 Date: May 17, 2007

(30) Foreign Application Priority Data
Nov. 19, 2004 (JP) 2004-335653

(51) Int. Cl. H05K 1/16; H05K 3/10

(52) U.S. Cl. 174/260; 29/846

(57) ABSTRACT

For the purpose of lighting multiple cold-cathode tubes at uniform luminance using a cold-cathode tube lighting device incorporating a multilayer substrate with built-in capacitors through a common power source and downsizing the cold-cathode tube lighting device, the multilayer substrate with built-in capacitors comprising at least four conductor layers overlaid is formed by heating and pressing dielectric layers, on one side of each of which a conductor layer is formed, to both sides of a dielectric layer, on both sides of which a conductor layer is formed, respectively, with bonding layers P1 and P2 interposed therebetween and by press-bonding these layers mutually, and specific conductor layers are electrically connected using connection parts formed on the inner faces of through holes.

### TECHNICAL FIELD

The present invention relates to a multilayer substrate with built-in capacitors and a method for manufacturing the same, and to a cold-cathode tube lighting device comprising the multilayer substrate with built-in capacitors, more particularly, to a cold-cathode tube lighting device for lighting multiple cold-cathode tubes.

### BACKGROUND ART

Fluorescent tubes are classified broadly into hot-cathode tubes and cold-cathode tubes depending on the configuration of the electrodes thereof. A hot-cathode tube (hereafter simply referred to as an HCFL) has a configuration wherein the electrodes thereof have filaments, the filaments are heated, and thermal electrons are emitted, thereby emitting light. On the other hand, a cold-cathode tube (hereafter simply referred to as a CCFL) has a configuration wherein the electrodes thereof are formed of substances that emit numerous electrons through the application of high voltage. In other words, unlike the HCFL, the CCFL is configured so as not to include filaments for emitting thermal electrons. For this reason, the CCFL is advantageous over the HCFL in terms of very small tube diameter, long life and low power consumption. Because of these advantages, the CCFLs are mainly used frequently for the backlight units of liquid crystal displays, the light sources of facsimiles and scanners, etc., more particularly, for the light sources of products strongly requested to be made thinner, smaller in size and lower in power consumption.

The CCFL has electrical characteristics of higher discharge start voltage, smaller discharge current (hereafter referred to as tube current) flowing between the electrodes at the time of discharging and higher impedance than the HCFL. In particular, the CCFL has a negative resistance characteristic wherein the resistance value across the electrodes drops abruptly as the tube current increases. The configuration of a cold-cathode tube lighting device (hereafter simply referred to as a CCFL lighting device) is devised in consideration of these electrical characteristics of the CCFL. In particular, since downsizing, thinning and electric power saving are emphasized for apparatuses to which the CCFLs are applied, the CCFL lighting device is also strongly requested to be made smaller in size, particularly thinner and lower in power consumption.

As a conventional CCFL lighting device, the lighting device disclosed in Japanese Patent Application Laid-Open Publication No. Hei 8-273862 is taken as an example. FIG. 12 is a circuit diagram showing the configuration of the conventional CCFL lighting device. The conventional CCFL lighting device shown in FIG. 12 has a high-frequency oscillation circuit 200, a step-up transformer 300 and an impedance matching part 400.

The high-frequency oscillation circuit 200 converts a direct-current voltage supplied from a direct-current power source 100 into an AC voltage having a high frequency and applies the AC voltage to the primary winding L1 of the step-up transformer 300. The step-up transformer 300 generates a voltage, which is extremely higher than the voltage applied to the primary winding L1, across both ends of the secondary winding L2 thereof. The high secondary voltage V is subjected to impedance matching using the impedance matching part 400 and applied across both ends of a CCFL 500. The impedance matching part 400 has a series circuit of a choke coil 401 and a capacitor 402, for example. The capacitor 402 includes stray capacitances in the periphery of the CCFL 500. The impedance matching between the step-up transformer 300 and the CCFL 500 is carried out using the impedance matching part 400 by adjusting the inductance of the choke coil 401 and the capacitance of the capacitor 402.

When the voltage is applied to the primary winding L1 of the step-up transformer 300 at the time when the CCFL is lit, the voltage VR across both ends of the CCFL 500 is raised abruptly by the resonance of the choke coil 401 and the capacitor 402 of the impedance matching part 400, and the voltage VR across both ends exceeds the discharge start voltage. As a result, the CCFL 500 starts discharging and begins to emit light. Then, the tube current IR flowing between the electrodes of the CCFL 500 increases; as the tube current IR increases, the resistance value of the CCFL 500 drops abruptly because of the negative resistance characteristics thereof. Owing to the abrupt drop of the resistance value of the CCFL 500, the voltage VR across both ends of the CCFL 500 drops. At that time, the tube current IR is maintained stably by the action of the impedance matching part 400, regardless of the variation in the voltage VR across both ends of the CCFL 500. In other words, the luminance of the CCFL 500 is maintained stably.

In the circuit diagram shown in FIG. 12, the secondary winding L2 of the step-up transformer 300 and the choke coil 401 are indicated as circuit elements different from each other. However, in an actual CCFL lighting device, the secondary winding of a leakage flux transformer is used for three actions: step-up, choking and impedance matching. Hence, the CCFL lighting device having such a leakage flux transformer was configured so as to be capable of reducing the number of components and downsizing the device. In other words, in the conventional CCFL lighting device, the leakage flux transformer was regarded as particularly advantageous in downsizing and thus used frequently.

Patent document 1: Japanese Patent Application Laid-Open Publication No. Hei 8-273862

Patent document 2: Japanese Patent Application Laid-Open Publication No. 2003-218536

Patent document 3: Japanese Patent Application Laid-Open Publication No. 2004-200263

Patent document 4: Japanese Patent Application Laid-Open Publication No. 2002-204073

### DISCLOSURE OF THE INVENTION

Problem to be Solved by the Invention

High luminance is particularly requested for the backlight unit of a liquid crystal display. Hence, in the case that rod-shaped CCFLs (cold-cathode tubes) are used for the backlight unit, it is desired that multiple CCFLs are installed. In this kind of backlight unit, it is desired that the multiple CCFLs have the same luminance. In addition, for the purpose of attaining downsizing, an important issue in the field of this kind of liquid crystal display, it was necessary that a lighting device for lighting the CCFLs should be small in size. For the purpose of meeting these requirements, it is desired that the multiple CCFLs should be connected in parallel so as to be driven at the same voltage.

However, it was difficult to connect the multiple CCFLs in parallel and to drive them at the same voltage because of the following reasons.

The CCFLs have negative resistance characteristics as described above. Hence, when the multiple CCFLs are simply connected in parallel, current concentration may occur in only one of the CCFLs at the time of lighting; if current concentration occurred, a phenomenon occurred occasionally wherein the only one CCFL in which the current concentration occurred was lit. Furthermore, even if the multiple CCFLs are connected in parallel to a common power source, wires connected between the power source and the respective CCFLs are different, more particularly, their lengths are different. Hence, the stray capacitance is different for each CCFL. Therefore, even if the multiple CCFLs are connected in parallel and driven, it is necessary to control the tube current for each CCFL, and a control circuit for eliminating the variation in tube current is required.

In the conventional CCFL lighting device, it was difficult to establish all of the following: using one leakage flux transformer as a common choke coil for multiple CCFLs, attaining highly accurate impedance matching between the one leakage flux transformer and each of the CCFLs and highly accurately controlling the tube currents of the individual CCFLs. Furthermore, the difficulty remained similarly even in the case that a piezoelectric transformer is used instead of the leakage flux transformer. Hence, in the conventional CCFL lighting device, one power source (leakage flux transformer, in particular) was installed for each CCFL, and the respective tube currents were controlled using the respective power sources. In other words, in the conventional CCFL lighting device, the power sources as many as the CCFLs were required. As a result, in the configuration of the conventional CCFL lighting device, it was difficult to reduce the number of components, and it was impossible to further downsize the whole device.

The present invention is intended to provide a cold-cathode tube lighting device capable of lighting multiple cold-cathode tubes (CCFLs) at the same luminance using one power source. In this CCFL lighting device, multiple ballast capacitors are formed of multilayer substrate; hence, the present invention is intended to provide a cold-cathode tube lighting device being further downsized, stable in performance and suited for mass production.

Means for Solving Problem

A multilayer substrate with built-in capacitors according to the present invention having at least four conductor layers overlaid via dielectric layers, comprises at least:

a first member on which a first conductor layer having a predetermined conductor pattern is overlaid on one face of a first dielectric layer,

a second member having a second conductor layer and a third conductor layer each having a predetermined conductor pattern and overlaid on both faces of a second dielectric layer, respectively,

a third member having a fourth conductor layer having a predetermined conductor pattern and overlaid on one face of a third dielectric layer,

a first bonding layer disposed between the other face of the first dielectric layer and one face of the second member so as to bond the faces mutually, and

a second bonding layer disposed between the other face of the third dielectric layer and the other face of the second member so as to bond the faces mutually, wherein

specific conductor patterns are connected using the connection parts of through holes formed at predetermined positions in the multilayer substrate with built-in capacitors, thereby forming multiple capacitor blocks among the conductor layers.

A method for manufacturing a multilayer substrate with built-in capacitors according to the present invention having at least four conductor layers overlaid via dielectric layers, comprises at least:

a step of producing a first member on which a first conductor layer having a predetermined conductor pattern is overlaid on one face of a first dielectric layer,

a step of producing a second member having a second conductor layer and a third conductor layer each having a predetermined conductor pattern and overlaid on both faces of a second dielectric layer, respectively,

a step of producing a third member having a fourth conductor layer having a predetermined conductor pattern and overlaid on one face of a third dielectric layer,

a step of disposing a first bonding layer between the other face of the first dielectric layer and one face of the second member,

a step of disposing a second bonding layer between the other face of the third dielectric layer and the other face of the second member,

a step of carrying out heating and pressing in a direction of sandwiching the first dielectric layer, the second dielectric layer and the third dielectric layer via the first bonding layer and the second bonding layer so as to bond the layers mutually,

a step of forming through holes at predetermined positions of specific conductor patterns, and

a step of forming multiple capacitor blocks among the conductor layers by forming connection parts on the inner faces of the through holes and by electrically connecting the specific conductor patterns.

A cold-cathode tube lighting device according to the present invention is equipped with:

a multilayer substrate with built-in capacitors, having multiple ballast capacitors formed of at least four conductor layers overlaid via dielectric layers, and

a low-impedance power source, having a low output impedance, for supplying power to cold-cathode tubes via the ballast capacitors,

the multilayer substrate with built-in capacitors, having at least four conductor layers overlaid via dielectric layers, comprising at least:

a first member on which a first conductor layer having a predetermined conductor pattern is overlaid on one face of a first dielectric layer,

a second member having a second conductor layer and a third conductor layer each having a predetermined conductor pattern and overlaid on both faces of a second dielectric layer, respectively,

a third member having a fourth conductor layer having a predetermined conductor pattern and overlaid on one face of a third dielectric layer,

a first bonding layer disposed between the other face of the first dielectric layer and one face of the second member so as to bond the faces mutually, and

a second bonding layer disposed between the other face of the third dielectric layer and the other face of the second member so as to bond the faces mutually, wherein

specific conductor patterns are connected using the connection parts of through holes formed at predetermined positions in the multilayer substrate with built-in capacitors, thereby forming multiple capacitor blocks among the conductor layers.

Generally speaking, in multiple cold-cathode tubes, stray capacitances in the periphery thereof vary owing to the differences in installation conditions (for example, wire length, wiring pattern, the distance between the tube wall of the cold-cathode tube and the outside of the device (for example, the case of a liquid crystal display), etc.), and the leak current flowing between the tube wall and the outside of the device varies in particular.

In the above-mentioned cold-cathode tube lighting device according to the present invention, the output impedance of the power source is suppressed, contrary to the presumption in the conventional cold-cathode tube lighting device. Instead, at least one ballast capacitor is connected to each of the cold-cathode tubes.

The capacitance of the ballast capacitor is preferably adjusted for each cold-cathode tube. Hence, the variation in capacitance among the ballast capacitors accurately coincides with the variation in stray capacitance among the multiple cold-cathode tubes. In other words, the impedance of each ballast capacitor is matched with the combined impedance of the stray capacitances in the periphery of each cold-cathode tube. As a result, among the multiple cold-cathode tubes, the tube currents are maintained uniformly, regardless of the variation in leak current owing to the differences in the installation conditions, in particular. By the adjustment of the capacitances of the ballast capacitors for each cold-cathode tube as described above, even if the wires between the low-impedance power source and the respective ballast capacitors are long and even if the capacitances are significantly different for the respective ballast capacitors, no variation occurs in tube current among the multiple cold-cathode tubes. Hence, luminance is maintained uniformly among the multiple cold-cathode tubes, regardless of the differences in the installation conditions.

In the configuration of the cold-cathode tube lighting device according to the present invention, the multiple cold-cathode tubes can be lit uniformly at the same luminance using the common low-impedance power source.

In the cold-cathode tube lighting device according to the present invention, the layout of the wiring is high in flexibility and can deal with long wires, in particular. At that time, the low-impedance power source is preferably installed on a substrate different from the multilayer substrate with built-in capacitors according to the present invention. Such substrate separation can be attained easily without impairing the uniformity of luminance among the multiple cold-cathode tubes.

Generally speaking, ballast capacitors and circuit elements can be configured so as to be small in size using a low-impedance power source. In addition, the temperature of the ballast capacitor when heated owing to power consumption is low. Hence, the multilayer substrate with built-in capacitors, on which the ballast capacitors are mounted can be separated from the substrate on which the low-impedance power source is mounted and can be installed very close to the cold-cathode tubes. As a result, the part comprising the multilayer substrate with built-in capacitors, on which the ballast capacitors are mounted and the cold-cathode tubes can be made thinner easily.

For example, when the cold-cathode tubes are used for the backlight unit of a liquid crystal display, the thinning of the liquid crystal display can be attained easily. In other words, the cold-cathode tube lighting device according to the present invention is particularly advantageous in the use as the backlight driving device of the liquid crystal display.

In the cold-cathode tube lighting device according to the present invention, the low-impedance power source is adopted, and the impedance of the ballast capacitors is set as high as the impedance of the CCFL. Hence, the capacitances of the ballast capacitors being used for the cold-cathode tube lighting device according to the present invention can be set small. Therefore, in the present invention, the ballast capacitors can be attained as the capacitances among the conductor layers of the substrate. At that time, since each ballast capacitor is wholly embedded inside the substrate, the size, particularly the thickness, of the ballast capacitor, is significantly smaller than that of the conventional one. As a result, even in the case that the multiple cold-cathode tubes are driven in parallel, the connection parts between the cold-cathode tube lighting device and the cold-cathode tubes can be configured so as to be small and particularly thin. The thinning at the connection parts between the cold-cathode tube lighting device and the cold-cathode tubes as described above is advantageous in the use as the backlight driving unit of the liquid crystal display in particular.

As described above, in the cold-cathode tube lighting device according to the present invention, the use of the multilayer substrate with built-in capacitors, having the ballast capacitors is extremely effective in downsizing the whole device.

In addition, since the thicknesses of the respective layers are formed so as to be accurately uniform inside the multilayer substrate with built-in capacitors according to the present invention, variation in the capacitances of the ballast capacitors in the multilayer substrate with built-in capacitors is very small.

Furthermore, in the multilayer substrate with built-in capacitors according to the present invention, the conductor layers can be formed easily even if their shapes are complicated, and the number of the layers of the multilayer substrate with built-in capacitors can be adjusted easily. Hence, multiple ballast capacitors can be connected easily in series or in parallel. Therefore, in the multilayer substrate with built-in capacitors according to the present invention, the ballast capacitors have a high degree of freedom for the setting of withstand voltage and capacitance.

In the multilayer substrate with built-in capacitors according to the present invention, the conductor layers are preferably formed of conductor films evaporated. Such conductor layers have the so-called self-healing property, that is, the conductor layers are fused at the occurrence time of overcurrent, thereby being capable of suppressing overcurrent. Hence, by the use of the multilayer substrate with built-in capacitors according to the present invention, the cold-cathode tubes and the cold-cathode tube lighting device are configured so as to be capable of avoiding breakdown owing to overcurrent.

In the cold-cathode tube lighting device according to the present invention, the impedance of the ballast capacitors, the combined impedance of the stray capacitances in the periphery of the cold-cathode tube and the impedance of the cold-cathode tube during lighting are preferably adjusted so as to be matched. In particular, the ballast capacitor has at least four conductor layers, and these conductor layers are closely attached mutually and integrated while being separated mutually electrically by interposing core members made of dielectric layers having insulation and a uniform thickness among the conductor layers. Furthermore, since the ballast capacitor is formed as the capacitance among the conductor layers of the multilayer substrate with built-in capacitors, the setting of the capacitance is easy, and the variation in capacitance is small. Hence, in the present invention, the impedance matching can be accurately adjusted for each combination of the ballast capacitors and the cold-cathode tube. With this configuration of the cold-cathode tube lighting device according to the present invention, since the tube currents are maintained uniformly among the multiple cold-cathode tubes, regardless of the variation in the stray capacitances in the periphery thereof, uniform luminance is maintained securely.

In the cold-cathode tube lighting device according to the present invention, since the ballast capacitors are wholly embedded inside the multilayer substrate with built-in capacitors, malfunction due to high temperature and failure due to dielectric breakdown can be avoided by adjusting the clearance between the surface of the multilayer substrate with built-in capacitors itself and the surface of the cold-cathode tube to a desired distance, unlike the conventional cold-cathode tube lighting device. Since the multilayer substrate with built-in capacitors according to the present invention is high in both heat resistance and withstand voltage, the clearance between the surface of the multilayer substrate with built-in capacitors and the surface of the cold-cathode tube can be set small. Hence, in the cold-cathode tube lighting device according to the present invention, the connection part between the cold-cathode tube and the multilayer substrate with built-in capacitors can be thinned easily. The improvement in thinning at the connection part is advantageous in the use as the backlight driving unit of a liquid crystal display in particular.

In the cold-cathode tube lighting device according to the present invention, it is preferable that the surface of the multilayer substrate with built-in capacitors, on which the ballast capacitors are mounted is installed so as to be orthogonal to the longitudinal direction (the central axis direction) of the cold-cathode tube. Hence, the connection part between the cold-cathode tube and the multilayer substrate with built-in capacitors can be downsized while the distance between the surface of the multilayer substrate with built-in capacitors and the surface of the cold-cathode tube is maintained within a safe range. Furthermore, in the configuration of the present invention, an end part (one of the electrodes) of the cold-cathode tube can be connected easily to the multilayer substrate with built-in capacitors, and the connection state thereof is maintained stably.

The surface of the multilayer substrate with built-in capacitors, on which the ballast capacitors are mounted is installed so as to be orthogonal to the longitudinal direction (the central axis direction) of the cold-cathode tube, and it is preferable to have a configuration in which, among the conductor layers constituting the ballast capacitors, the conductor layer nearest the cold-cathode tube is connected to the electrode of the cold-cathode tube, and the conductor layer farthest from the cold-cathode tube is connected to the low-impedance power source. With this configuration, the variation in the potential at the electrode is further suppressed among the multiple cold-cathode tubes, and the uniformity of the tube current, namely, the uniformity of luminance, is improved further.

In the cold-cathode tube lighting device according to the present invention, the low-impedance power source preferably includes a transformer connected to the ballast capacitors and having an output impedance lower than the combined impedance of the multiple cold-cathode tubes. In the cold-cathode tube lighting device according to the present invention, since the output impedance of the transformer is suppressed, contrary to the presumption in the conventional cold-cathode tube lighting device, a power source having a low output impedance is attained.

In the present invention, as a means being effective in reducing the output impedance of the transformer, for example, the transformer is configured so as to have a core, a primary winding wound around the core and a secondary winding wound around the inside or outside or both the inside and outside of the primary winding. With this configuration, the leakage flux is reduced, and the output impedance is suppressed in the present invention. Furthermore, in the present invention, adverse effects (for example, noise generation) to peripheral apparatuses due to leakage flux are suppressed.

In the cold-cathode tube lighting device according to the present invention, the low-impedance power source may use a power transistor instead of the above-mentioned transformer, and this power transistor may be connected to the ballast capacitors. The use of the power transistor can reduce the output impedance easily and effectively. Therefore, the cold-cathode tube lighting device according to the present invention can uniformly light a larger number of cold-cathode tubes.

### EFFECT OF THE INVENTION

Since the multilayer substrate with built-in capacitors according to the present invention is formed of multiple layers, the thicknesses of which are accurately uniform inside the substrate, variation in the capacitances of ballast capacitors formed can be set very small. In addition, in the multilayer substrate with built-in capacitors according to the present invention, the conductor layers can be formed easily even if their shapes are relatively complicated, and the number of the layers of the substrate can be adjusted relatively easily. Hence, in the multilayer substrate with built-in capacitors according to the present invention, multiple ballast capacitors can be connected easily in series or in parallel, and the ballast capacitors have a high degree of freedom for the setting of withstand voltage and capacitance.

In addition, the cold-cathode tube lighting device incorporating the multilayer substrate with built-in capacitors according to the present invention comprises multiple ballast capacitors, at least one of which is connected to each of multiple cold-cathode tubes, and a common low-impedance power source, thereby being capable of uniformly lighting the multiple cold-cathode tubes using the common power source, unlike the conventional cold-cathode tube lighting device.

Furthermore, the multilayer substrate with built-in capacitors according to the present invention has at least four conductor layers, and these conductor layers are closely attached mutually and integrated while being separated mutually electrically by interposing core members made of dielectric layers having insulation and a uniform thickness among the conductor layers. Still further, in the present invention, since the ballast capacitors having the capacitances among the opposed multiple conductor layers are formed in the multilayer substrate with built-in capacitors, it is possible to securely produce a multilayer substrate including capacitors having a uniform capacitance; hence, an apparatus having such a multilayer substrate with built-in capacitors can be attained easily as an apparatus that can be mass-produced.

In the cold-cathode tube lighting device incorporating the multilayer substrate with built-in capacitors according to the present invention, the ballast capacitors are formed as the capacitances among the conductor layers of the multilayer substrate with built-in capacitors. Hence, since the ballast capacitors are configured so as to be wholly embedded inside the substrate, the connection parts between the cold-cathode tubes and the cold-cathode tube lighting device can be formed very thin. In particular, when the cold-cathode tube lighting device according to the present invention is used as the backlight driving unit of a liquid crystal display, the use of the ballast capacitors configured as described above is very effective in thinning the liquid crystal display.

### BRIEF DESCRIPTION OF THE DRAWINGS

FIG. 1 is a perspective view showing the configuration of the backlight unit of a liquid crystal display in which a cold-cathode tube lighting device according to Embodiment 1 of the present invention is installed;

FIG. 2 is a sectional view of the liquid crystal display, cross-sectioned on line II-II of FIG. 1;

FIG. 3 is a circuit diagram showing the configuration of the CCFL lighting device according to Embodiment 1 of the present invention;

FIG. 4 is an exploded view schematically showing the configuration of a step-up transformer included in the CCFL lighting device according to Embodiment 1 of the present invention;

FIG. 5 is a sectional view of the step-up transformer 5, cross-sectioned on line V-V shown in FIG. 4;

FIG. 6 is a schematic view showing various configurations of the multilayer substrate with built-in capacitors according to the present invention;

FIG. 7 is a magnified view showing the vicinity of the connection part between a second substrate and a CCFL 20 in the CCFL lighting device according to Embodiment 1 of the present invention;

FIG. 8 is a plan view showing the patterns of the conductor layers inside a second block in the CCFL lighting device according to Embodiment 1 of the present invention;

FIG. 9 is a partially sectional view of the second block in the CCFL lighting device according to Embodiment 1 of the present invention;

FIG. 10 is a view illustrating the structure of the multilayer substrate with built-in capacitors of the second block in the CCFL lighting device according to Embodiment 1 of the present invention and illustrating the method for manufacturing the same;

FIG. 11 is a view illustrating various connection states of the multilayer substrate with built-in capacitors in the CCFL lighting device according to Embodiment 1 of the present invention; and

FIG. 12 is a circuit diagram showing the configuration of the conventional CCFL lighting device.

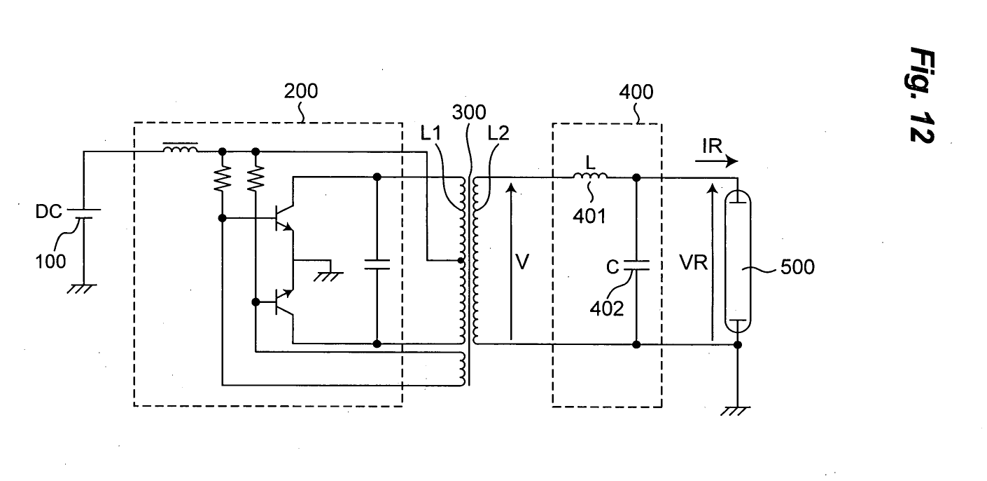

### EXPLANATION OF LETTERS AND NUMERALS

20 cold-cathode tube (CCFL)

50 second multilayer substrate

21A, 21B conductor patterns

22A, 22B conductor patterns

23A, 23B conductor patterns

24A, 24B conductor patterns

61 first through hole

62 second through hole

63 third through hole

64 fourth through hole

71 first connection part

72 second connection part

73 third connection part

74 fourth connection part

81 first lead wire

82 second lead wire

B1, B2, B3 core members

P1, P2 prepregs

CB1, CB2, CB3 ballast capacitors

X1 first conductor layer

X2 second conductor layer

X3 third conductor layer

X4 fourth conductor layer

### BEST MODE FOR CARRYING OUT THE INVENTION

Embodiment 1 serving as the best modes of a multilayer substrate with built-in capacitors for use in a cold-cathode tube lighting device according to the present invention and the cold-cathode tube lighting device according thereto will be described below referring to the accompanying drawings.

### Embodiment 1

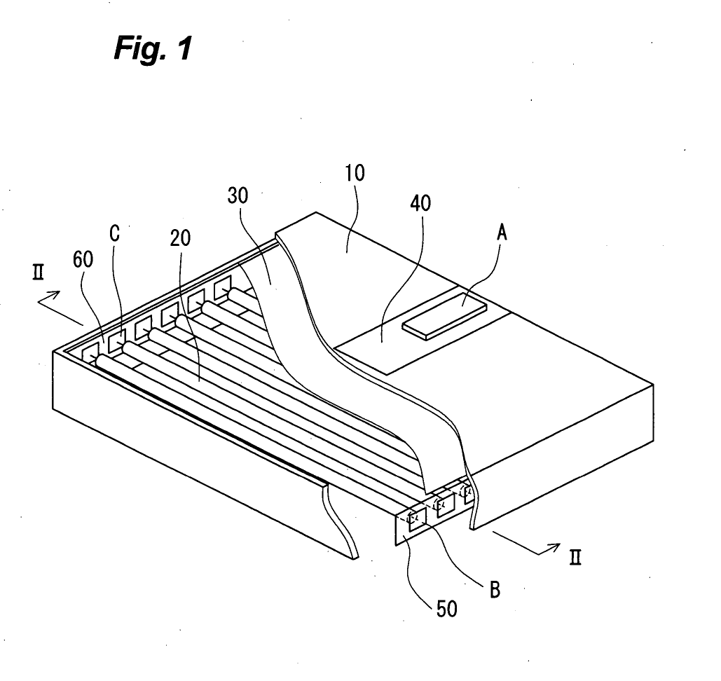

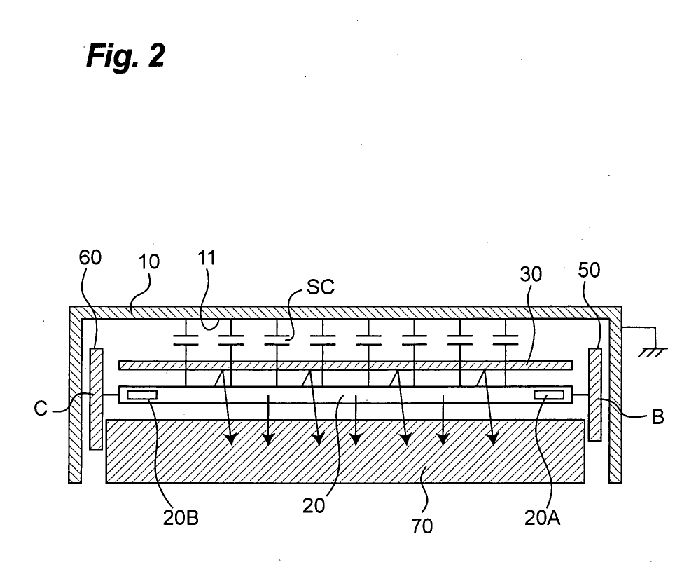

FIG. 1 is a perspective view showing the configuration of the backlight unit of a liquid crystal display in which a cold-cathode tube lighting device (hereafter simply referred to as a CCFL lighting device) according to Embodiment 1 of the present invention is installed. In FIG. 1, the back face of the case 10 of the liquid crystal display is shown upward. In addition, the back plate and side plates of the case 10 are partly removed to expose the inside of the case 10. FIG. 2 is a sectional view cross-sectioned along line II-II shown in FIG. 1. The arrows shown in FIG. 1 indicate the visual line direction in the sectional view of FIG. 2.

The liquid crystal display shown in FIGS. 1 and 2 has the case 10, multiple cold-cathode tubes (hereafter simply referred to as CCFLs) 20 disposed in parallel, a reflecting plate 30 disposed on the back face side of the CCFLs 20, a first substrate 40 provided on the back face (the face not opposed to the CCFLs 20) of the case 10, a second substrate 50 connected to one side electrodes 20A of the CCFLs 20, a third substrate 60 connected to the other side electrodes 20B of the CCFLs 20, and a liquid crystal panel 70 (see FIG. 2) disposed on the front face side of the CCFL 20.

The circuit configuration of the CCFL lighting device according to Embodiment 1 of the present invention is mainly divided into three blocks: a first block A, a second block B and a third block C, and the circuit elements of the respective blocks A, B and C are mounted on the first substrate 40, the second substrate 50 and the third substrate 60, respectively.

The case 10 is a box made of metal, for example, and is grounded. Since the case 10 is grounded as described above, both the electromagnetic noise radiated from the CCFLs 20 and the electromagnetic noise coming from the outside are shielded.

As shown in FIG. 2, the front face side (the lower side in FIG. 2) of the case 10 is open. Inside the case 10, the reflecting plate 30, the CCFLs 20 and the liquid crystal panel 70 are disposed in this order in the direction from the back face side to the front face side thereof.

The CCFLs 20, having the shape of a thin rod and being multiple in number (for example 16), are disposed in parallel with one another in substantially one plane. Both ends of each CCFL 20 are covered with a material having insulation, heat resistance and contractility, such as rubber tubes (not shown). These tubes are supported on brackets (not shown) secured to the case 10. In this way, the respective CCFLs 20 are held in parallel in substantially one plane using the brackets and arranged such that the intervals between the CCFLs 20 are equal. In other words, the respective CCFLs 20 are parallel in the longitudinal direction of the liquid crystal display and arranged in parallel at equal intervals in the crosswise direction.

The second substrate 50 and the third substrate 60 connected to the electrodes 20A and 20B derived from both end sides of the respective CCFLs 20 are installed on both end sides of the respective CCFLs 20 in a direction orthogonal to the longitudinal direction (the central axis direction) of the CCFLs 20, for example. Since the second substrate 50 and the third substrate 60 are disposed as described above, the respective surfaces of the second substrate 50 and the third substrate 60 are positioned so that the distance from the CCFLs 20 is maintained in a safe range. Hence, the second substrate 50 and the third substrate 60 are disposed securely so as to have an optimal minimum distance to the respective CCFLs 20, whereby the downsizing of the backlight unit of the liquid crystal display is attained.

Furthermore, by the disposition of the second substrate 50 and the third substrate 60 as described above, the terminals at both ends of the CCFLs 20 can be mounted easily on the second substrate 50 and the third substrate 60, and the respective CCFLs 20 are held stably.

In the backlight unit comprising the CCFL lighting device according to Embodiment 1, the second substrate 50 and the third substrate 60 are each formed of a multilayer printed substrate. The second substrate 50 and the third substrate 60 may each be formed of a flexible multilayer printed substrate. The first substrate 50 and the second substrate 60 are made of a material having heat resistance and flame retardancy and being capable of withstanding high voltage. Hence, the second substrate 50 and the third substrate 60 are configured so as to be high in heat resistance and flame retardancy and so as to withstand high voltage.

The second substrate 50 and the third substrate 60 are each formed of multiple conductor layers and preferably formed of copper foils and multiple insulation layers. The insulation layers according to Embodiment 1 are each formed of a dielectric member, for example, an epoxy resin substrate containing glass fibers as a reinforcing material. The second block B in the CCFL lighting device according to Embodiment 1 is a circuit formed of the patterns of the conductor layers of the second substrate 50. In addition, the third block C is a circuit formed of the patterns of the conductor layers of the third substrate 60. The second block B and the third block C are each provided for each CCFL 20. The second block B and the third block C are connected to the electrodes 20A and 20B (see FIG. 2) (hereafter referred to as a first electrode 20A and a second electrode 20B) provided at both ends of each CCFL 20, respectively. Herein, in the electrodes 20A and 20B at both ends of the CCFL 20, the first electrode 20A is connected to a conductor pattern in the second block B, and the second electrode 20B is connected to a conductor pattern in the third block C.

The second block B is wholly embedded inside the second substrate 50. In addition, the third block C is wholly embedded inside the third substrate 60. Hence, by adjusting the clearance between the surface of each of the second substrate 50 and the third substrate 60 and the surface of each CCFL 20 to a desired distance, the second block B and the third block C can avoid malfunction due to high temperature and failure due to dielectric breakdown.

Since the second substrate 50 and the second substrate 60 according to Embodiment 1 are high in heat resistance and withstand voltage, the clearance between the surface of each of the second substrate 50 and the third substrate 60 and the surface of each CCFL 20 may be made small. It is particularly preferable that the second substrate 50 and the third substrate 60 are disposed inside the case 10 and in the vicinity of the electrodes on both end sides of the CCFL 20. At this time, the clearance between the surface of each of the second substrate 50 and the second substrate 60 and the surface of each CCFL 20 is determined by the temperature difference and the potential difference between the two and is 0.1 to 10 [mm], for example. As described above, in the CCFL lighting device according to Embodiment 1 of the present invention, the connection parts for connecting the CCFLs 20 to the respective substrates (50, 60) can be set small, and the thickness (the distance between the front face and the back face) of the CCFL lighting device can be set thin.

The respective circuits of the second block B and the third block C are connected to the circuit of the first block A on the first substrate 40. In FIG. 1, the wiring from the circuit of the first block A to the second block B and the third block C is not shown. In Embodiment 1, the first substrate 40 is installed on the outside on the rear face side of the case 10. However, the first substrate 40 is not limited to be installed on the outside on the rear face side of the case 10 but is set depending on the structure of an apparatus in which the CCFL lighting device is incorporated. The first block A is connected to a direct-current power source (not shown).

The CCFL lighting device distributes the electric power supplied from the direct-current power source to each CCFL 20 via the three blocks A, B and C. As a result, each CCFL 20 emits light. The light emitted from the CCFLs 20 enters the liquid crystal panel 70 directly or after being reflected by the reflecting plate 30 (see the arrows shown in FIG. 2). The liquid crystal panel 70 carries out control to shield the incident light emitted from the CCFLs 20 using a predetermined pattern, whereby the pattern is displayed on the front face side of the liquid crystal panel 70.

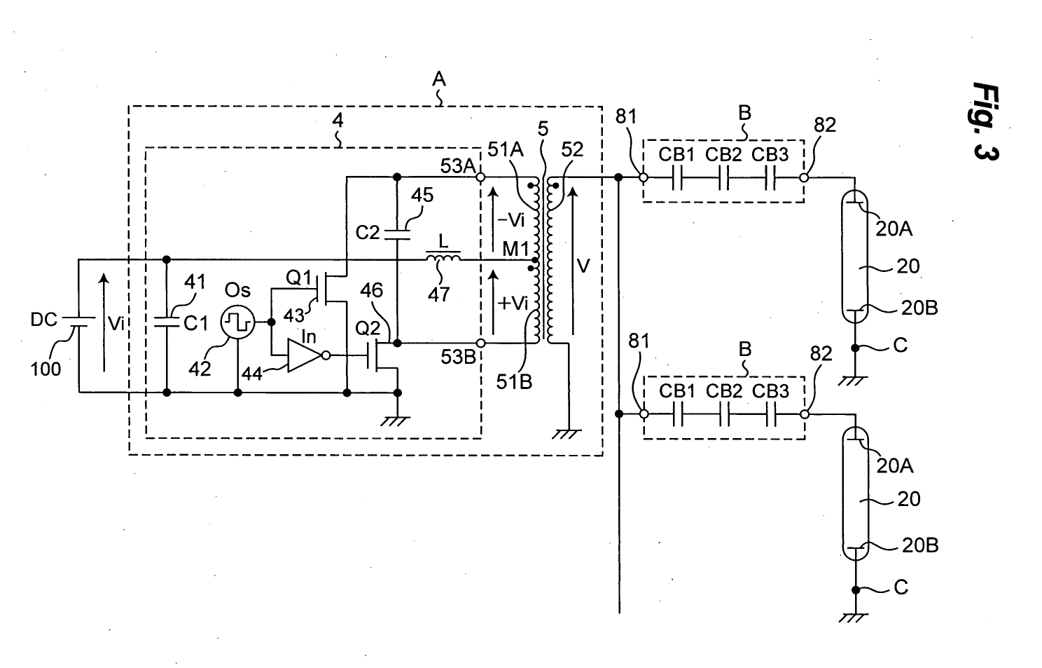

FIG. 3 is a circuit diagram showing the configuration of the CCFL lighting device according to Embodiment 1 of the present invention. The CCFL lighting device mainly comprises the three blocks A, B and C as described above.

The first block A has a high-frequency oscillation circuit 4 and a step-up transformer 5, and is configured as a parallel resonance type push-pull inverter. The high-frequency oscillation circuit 4 is configured so as to include a first capacitor 41, an oscillator 42, a first transistor 43, an inverter 44, a second capacitor 45, a second transistor 46 and an inductor 47. The step-up transformer 5 includes two primary windings 51A and 51B divided at the neutral point M1 thereof and a secondary winding 52.

The positive electrode of a direct-current power source 100 is connected to one terminal of the inductor 47, and the negative electrode thereof is grounded. The first capacitor 41 is connected across both electrodes of the direct-current power source 100. The other terminal of the inductor 47 is connected to the neutral point M1 between the primary windings 51A and 51B of the step-up transformer 5. A second capacitor C2 is connected across the other terminal 53A of the first primary winding 51A and the other terminal 53B of the second primary winding 51B. The input terminal 53A of the first primary winding 51A is further connected to one terminal of the first transistor 43. The terminal 53B of the second primary winding 51B is further connected to one terminal of the second transistor 46. The other terminals of the first transistor 43 and the second transistor 46 are both grounded. The two transistors 43 and 46 being used for Embodiment 1 are preferably MOS FETs. In addition, the first transistor 43 and the second transistor 46 in the CCFL lighting device according to the present invention may also be IGBTs or bipolar transistors. The oscillator 42 is directly connected to the control terminal of the first transistor 43, and the output signal from the inverter 44 is fed to the control terminal of the second transistor 46.

The direct-current power source 100 maintains its output voltage Vi at a constant value (for example, 16 [V]). The first capacitor 41 stably maintains the input voltage Vi supplied from the direct-current power source 100. The oscillator 42 outputs a pulse wave having a constant frequency (for example, 45 [kHz]) to the control terminals of the two transistors 43 and 46. The inverter 44 carried out inversion so that the polarity of the pulse wave being input to the control terminal of the second transistor 46 is made opposite to the polarity of the pulse wave being input to the control terminal of the first transistor 43. Hence, the two transistors 43 and 46 turn ON and OFF alternately at the same frequency as the frequency of the oscillator 42. As a result, the input voltage Vi is alternately applied to the primary windings 51A and 51B of the step-up transformer 5. The inductor 47 and the second capacitor 45 cause resonance at each application of the voltage, and the polarity of the secondary voltage V of the step-up transformer 5 is inverted at the same frequency as the frequency of the oscillator 42. The effective value of the secondary voltage V is substantially equal to the product of the voltage Vi applied to the primary winding 51A and 51B and the step-up ratio (namely, the winding ratio between the primary winding 51A and the secondary winding 52) of the step-up transformer 5. In the configuration of the cold-cathode tube lighting device according to Embodiment 1, the effective value of the secondary voltage V is preferably set at approximately 1.5 times the lamp voltage of the CCFL 20 (for example, 1800 [V]).

As described above, in the first block A, the voltage Vi from the direct-current power source 100 is converted into the alternating-current voltage V having a high frequency (for example, 45 [kHz]). The first block A according to the present invention is not limited to the parallel resonance type push-pull inverter described above, but may be an inverter of another type (including a transformer).

In the CCFL lighting device according to Embodiment 1 of the present invention, the leakage flux of the step-up transformer 5 is suppressed small as described below. Hence, the first block A functions as a power source having a low output impedance, that is, a low impedance power source.

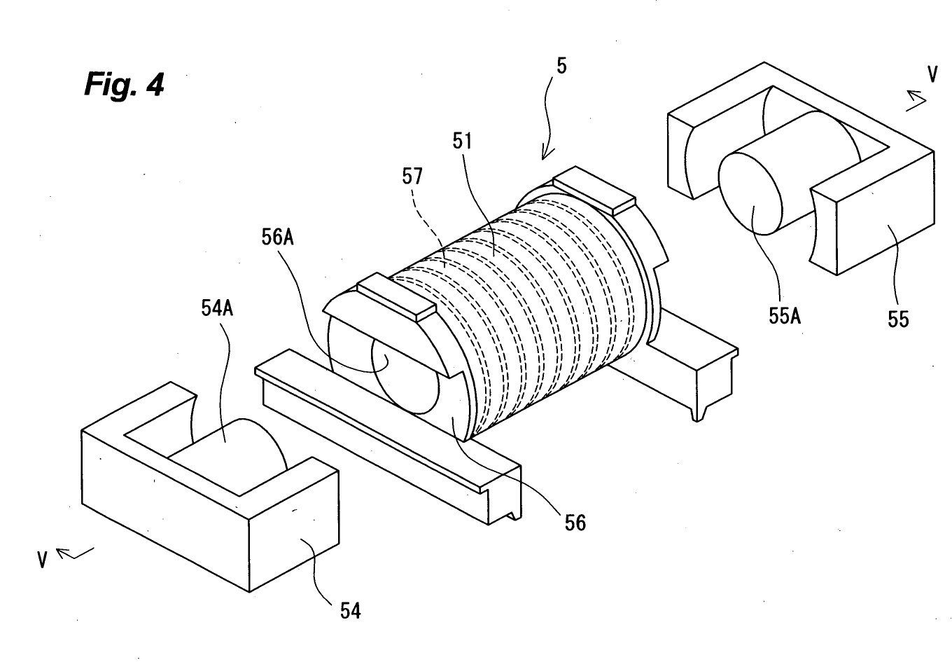

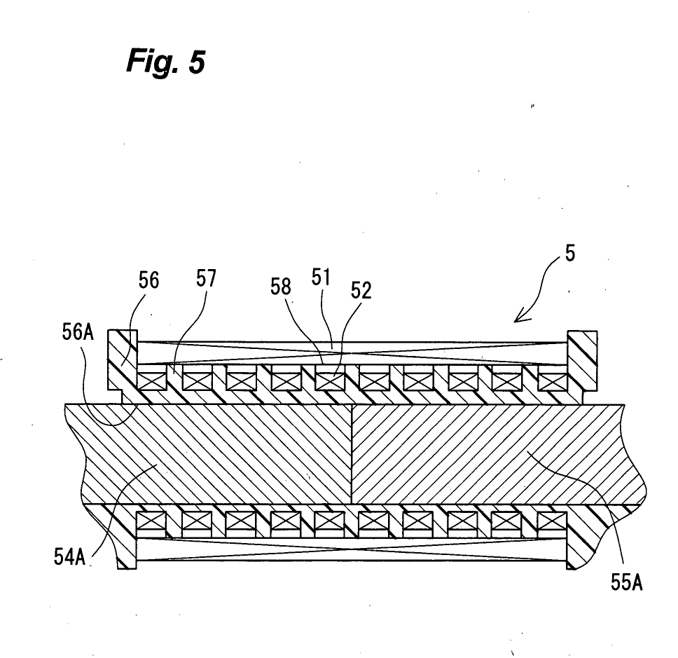

FIG. 4 is an exploded view schematically showing the configuration of the step-up transformer 5 being used for the CCFL lighting device according to Embodiment 1. FIG. 5 is a sectional view of the step-up transformer 5, cross-sectioned along line V-V shown in FIG. 4. The arrows shown in FIG. 4 indicate the visual line direction in the sectional view of FIG. 5.

As shown in FIGS. 4 and 5, the step-up transformer 5 according to Embodiment 1 is configured so as to include a primary winding 51, a secondary winding 52, two E-shaped cores 54 and 55, a bobbin 56 and an insulating tape 58. The primary winding 51 of the step-up transformer 5 is the combination of the two primary windings 51A and 51B shown in FIG. 3 described above. The bobbin 56 is made of a synthetic resin, for example, and is formed into a cylindrical shape having a hollow part 56A. Into the hollow part 56A, the respective central protrusions 54A and 55A of the E-shaped cores 54 and 55 are inserted through openings on both sides. On the outer circumferential face of the bobbin 56, multiple partitions 57 are formed at equal intervals in the axial direction.

As the method for assembling the step-up transformer 5, first, the secondary winding 52 is wound between the partitions 57 of the bobbin 56. Next, the insulating tape 58 is wound around the outside of the secondary winding 52. In the end, the primary winding 51 is wound around the outside of the insulating tape 58. Leakage flux is reduced significantly by winding the primary winding 51 and the secondary winding 52 around the outer circumferential face of the bobbin 56 so as to be overlaid as described above. Hence, the loss of the step-up transformer 5 is reduced, and the output impedance can be set low. In particular, the output impedance is set so as to be lower than the combined impedance of all the multiple CCFLs 20 connected in parallel (see FIG. 3). Although Embodiment 1 is configured such that the primary winding 51 is wound around the outside of the secondary winding 52, the secondary winding 52 may be wound around the outside of the primary winding 51, or the primary winding 51 may be wound around both the inside and outside of the secondary winding 52.

In the step-up transformer 5 according to Embodiment 1, the secondary winding 52 is wound around the bobbin 56 by division winding. In addition, the secondary winding may be configured so as to be wound around the bobbin by honeycomb winding in which the secondary winding is wound in such a hexagonal shape as the shape of a honeycomb. With this configuration, discharge between the windings is prevented, and the capacitance between the wires is suppressed small. Therefore, the self-resonant frequency of the secondary winding 52 of the step-up transformer 5 can be set sufficiently high.

Next, a specific configuration of the second block B in the CCFL lighting device according to Embodiment 1 will be described.

As shown in FIG. 3, the second block B connected to the electrode 20A of each CCFL 20, one of the electrodes thereof, is configured so as to be formed of a series connection of three ballast capacitors CB1, CB2 and CB3, for example. In the configuration according to Embodiment 1 shown in FIG. 3, the case in which the second block B is configured so as to be formed of a series connection of the three ballast capacitors CB1, CB2 and CB3 is described; however, the second block B can have another configuration. For example, the second block B can be formed of multiple capacitors connected in parallel or formed of a combination of multiple capacitors connected in series and those connected in parallel. When the second block B is configured so as to be formed of multiple capacitors connected in parallel, the capacitance of the capacitor can be set large.

The second block B in the CCFL lighting device according to Embodiment 1 comprises capacitors having a multilayer structure including conductor layers and insulation layers in the second substrate 50. In the second block B, multiple conductor layers overlaid via insulation layers serving as dielectric members are formed; in the second block B having the multiple conductor layers as described above, one end sides thereof are connected in parallel to form a capacitor to be connected to each CCFL 20. With the configuration of this parallel connection, the capacitance value of the capacitor of the second block B can be set large.

A case wherein the capacitors formed in each second block B are three ballast capacitors CB1, CB2 and CB3, for example, will be described below. The three ballast capacitors CB1, CB2 and CB3 are formed using the interlayer capacitances among four conductor layers overlaid. A through hole in which a connection part for conduction among the predetermined conductor layers is passed is formed in each of the ballast capacitors CB1, CB2 and CB3, and the conductor film on the inner face of this through hole serves as a surface electrode. In other words, multiple conductor layers are connected in a comb structure using the connection parts passing through the through holes.

The capacitances of the ballast capacitors CB1, CB2 and CB3 are determined by the areas of the conductor layers and the sizes of the insulation layers made of dielectric members in the second substrate 50. Although Embodiment 1 is described with respect to the case having the three ballast capacitors CB1, CB2 and CB3, since the number of the ballast capacitors is determined by the relationship between the withstand voltage among the conductor layers and the withstand voltage required for the whole of the capacitors, the number is not limited to three. Furthermore, changing the number of the ballast capacitors is done easily as described later.

In other words, increasing the withstand voltage required for the whole of the capacitors is made possible by setting the distance between the conductor layers large and/or by connecting a desired number of ballast capacitors in series. For this reason, a capacitor having a withstand voltage conforming to a CCFL provided to serve as a light source can be formed easily using a multilayer substrate.

Hence, the capacitor for the CCFL can have the predetermined capacitance and withstand voltage by designing that the distance between the conductor layers and the connection between the conductor layers have the desired configurations.

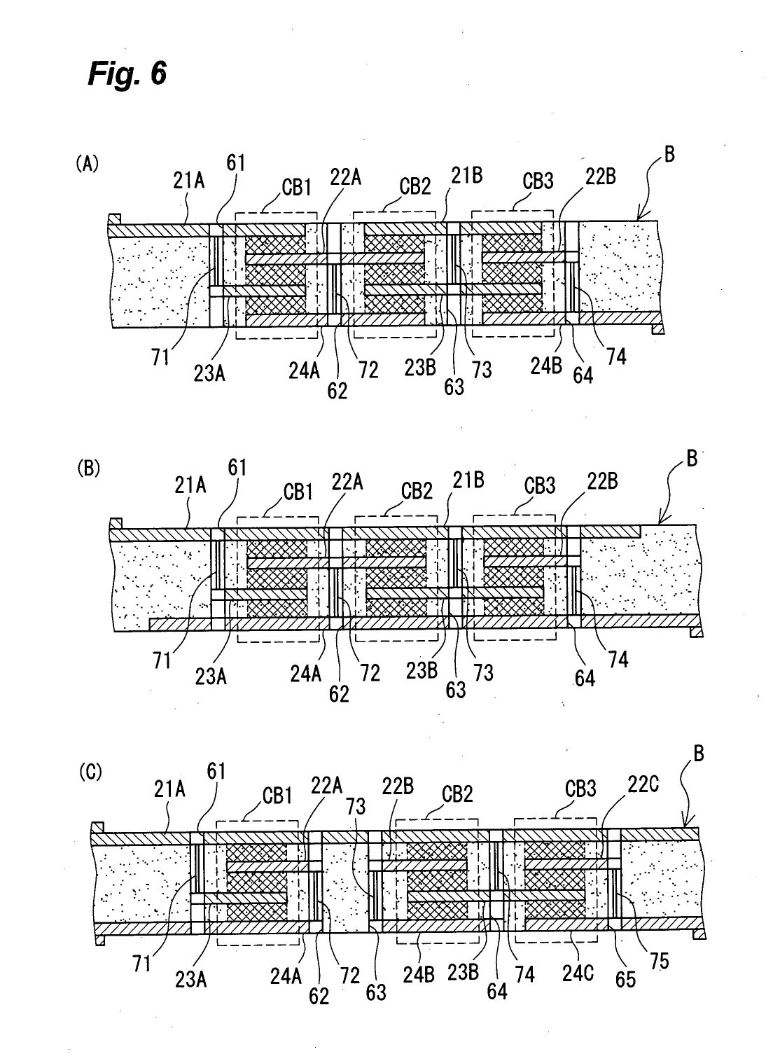

FIG. 6 is a schematic view showing the structure of the multilayer substrate with built-in capacitors of the second block B formed in the second substrate 50 in the CCFL lighting device. In FIG. 6, the structural view in (A) shows the multilayer substrate with built-in capacitors in the CCFL lighting device according to Embodiment 1. In (A) of FIG. 6, the regions enclosed with broken lines are the ballast capacitors CB1, CB2 and CB3 in the order from the left.

As shown in (A) of FIG. 6, the patterns of four-layer conductor layers are formed in the second block B. In addition, each conductor layer is divided into multiple conductor pieces depending on the shape of the pattern. The first conductor layer is electrically separated into conductor patterns 21A and 21B. Similarly, the second conductor layer is separated into conductor patterns 22A and 22B, the third conductor layer is separated into conductor patterns 23A and 23B, and the fourth conductor layer is separated into conductor patterns 24A and 24B. Between these conductor layers, insulation layers made of dielectric members are formed.

The conductor pattern 21A of the first layer and the conductor pattern 23A of the third layer are connected electrically using a first connection part 71 formed inside a first through hole 61. The conductor pattern 22A of the second layer and the conductor pattern 24A of the fourth layer are connected electrically using a second connection part 72 formed inside a second through hole 62. The conductor pattern 21B of the first layer and the conductor pattern 23B of the third layer are connected electrically using a third connection part 73 formed inside a third through hole 63. The conductor pattern 22B of the second layer and the conductor pattern 24B of the fourth layer are connected electrically using a fourth connection part 74 formed inside a fourth through hole 64.

In the second block B configured as described above, the regions in which the conductor patterns are overlapped form interlayer capacitors. In other words, the overlapping part of the conductor patterns 21A and 22A, the overlapping part of the conductor patterns 22A and 23A, and the overlapping part of the conductor patterns 23A and 24A form interlayer capacitors. The ballast capacitor CB1 is formed by the parallel connection of these interlayer capacitors. In (A) of FIG. 6, the interlayer capacitors, that is, the overlapping parts, are regions indicated by cross-hatching.

Similarly, the ballast capacitor CB2 is formed of the overlapping parts of the conductor patterns 21B and 22A, and 23B and 24A, and the ballast capacitor CB3 is formed of the overlapping parts of the conductor patterns 21B and 22B, and 23B and 24B.

In the second block B, the ballast capacitors CB1, CB2 and CB3 configured as described above are connected in series, and the predetermined capacitor withstand voltage is obtained.

In FIG. 6, (B) and (C) are views schematically showing ballast capacitors being different in structure from those in the multilayer substrate with built-in capacitors according to Embodiment 1 shown in (A).

In the multilayer substrate with built-in capacitors shown in (B) of FIG. 6, the first conductor layer is formed of a conductor pattern 21A. The second conductor layer is separated into conductor patterns 22A and 22B, the third conductor layer is separated into conductor patterns 23A and 23B, and the fourth conductor layer is formed of a conductor pattern 24A. Among these conductor layers, insulation layers made of dielectric members are formed.

The conductor pattern 21A of the first layer and the conductor pattern 23A of the third layer are connected electrically using a first connection part 71 formed inside a first through hole 61. The conductor pattern 22A of the second layer and the conductor pattern 24A of the fourth layer are connected electrically using a second connection part 72 formed inside a second through hole 62. The conductor pattern 21A of the first layer and the conductor pattern 23B of the third layer are connected electrically using a third connection part 73 formed inside a second through hole 63. The conductor pattern 22B of the second layer and the conductor pattern 24A of the fourth layer are connected electrically using a fourth connection part 74 formed inside a fourth through hole 64.

In the second block B configured as described above and shown in (B) of FIG. 6, the ballast capacitor CB1 is formed of the overlapping parts of the conductor patterns 21A and 22A, and 23A and 24A, and the ballast capacitor CB2 is formed of the overlapping parts of the conductor patterns 21A and 22A, and 23B and 24A, and the ballast capacitor CB3 is formed of the overlapping parts of the conductor patterns 21A and 22B, and 23B and 24A. The ballast capacitors CB1, CB2 and CB3 shown in (B) of FIG. 6 are connected in parallel, and the predetermined capacitor capacitance is obtained.

In the case that the ballast capacitors CB1, CB2 and CB3 are connected in parallel, the conductor patterns of the respective layers are made approximately the same, without being formed of multiple pattern shapes, whereby it is possible to have a configuration wherein one ends of the conductor patterns of the respective layers are connected to form a comb structure.

In the multilayer substrate with built-in capacitors shown in (C) of FIG. 6, the first conductor layer is formed of a conductor pattern 21A. The second conductor layer is separated into conductor patterns 22A, 22B and 22C, the third conductor layer is separated into conductor patterns 23A and 23B, and the fourth conductor layer is separated into conductor patterns 24A, 24B and 24C. Among these conductor layers, insulation layers made of dielectric members are formed.

The conductor pattern 21A of the first layer and the conductor pattern 23A of the third layer are connected electrically using a first connection part 71 formed inside a first through hole 61. The conductor pattern 22A of the second layer and the conductor pattern 24A of the fourth layer are connected electrically using a second connection part 72 formed inside a second through hole 62. The conductor pattern 22B of the second layer and the conductor pattern 24B of the fourth layer are connected electrically using a third connection part 73 formed inside a third through hole 63. The conductor pattern 21A of the first layer and the conductor pattern 23B of the third layer are connected electrically using a fourth connection part 74 formed inside a fourth through hole 64. The conductor pattern 22C of the second layer and the conductor pattern 24C of the fourth layer are connected electrically using a fifth connection part 75 formed inside a fifth through hole 65.

In the second block B configured as described above and shown in (C) of FIG. 6, the ballast capacitor CB1 is formed of the overlapping parts of the conductor patterns 21A and 22A, and 23A and 24A, and the ballast capacitor CB2 is formed of the overlapping parts of the conductor patterns 21A and 22B, and 23B and 24B, and the ballast capacitor CB3 is formed of the overlapping parts of the conductor patterns 21A and 22C, and 23B and 24C. The respective ballast capacitors CB1, CB2 and CB3 shown in (C) of FIG. 6 are configured so as to be independent and have predetermined capacitor capacitances.

In the multilayer substrate with built-in capacitors shown in (C) of FIG. 6, the capacitance of each of the ballast capacitors CB1, CB2 and CB3 is the combined value of the capacitances among the respective conductor layers. Furthermore, in the multilayer substrate with built-in capacitors, an output terminal is formed in each of the ballast capacitors CB1, CB2 and CB3. Hence, in the multilayer substrate with built-in capacitors shown in (C) of FIG. 6, the connection method and configuration of the ballast capacitors CB1, CB2 and CB3 can be selected in consideration of the capacitor withstand voltage and capacitance value. In other words, when the capacitor withstand voltage is required, the multiple ballast capacitors are connected in series (for example, the connection state shown in (A) of FIG. 6). In addition, when the capacitor capacitance is required, the multiple ballast capacitors are connected in parallel (for example, the connection state shown in (B) of FIG. 6).

Hence, configuring a multilayer substrate with built-in capacitors, having a desired capacitor withstand voltage and a desired capacitor capacitance is made possible by appropriately selecting the number of conductor layers, the method for connection among the conductor layers and the number of the conductor patterns in each conductor layer.

Next, a specific configuration of the multilayer substrate with built-in capacitors, which is provided in the backlight unit incorporating the CCFL lighting device according to Embodiment 1 will be described.

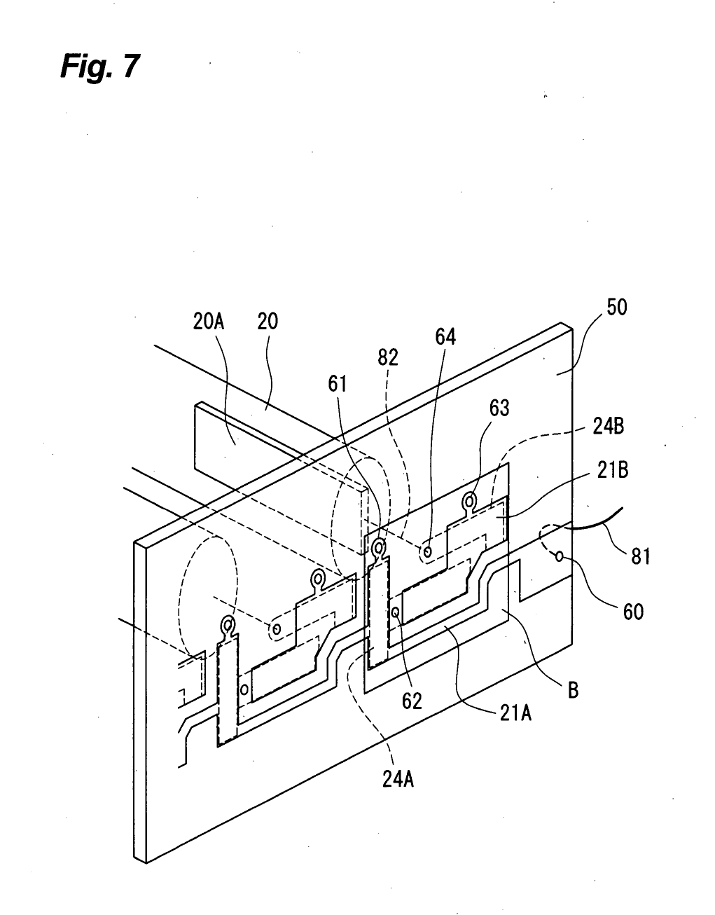

FIG. 7 is a perspective view showing the vicinity of the connection part between the second substrate 50 having the second block B and the CCFL 20.

The second substrate 50 is installed upright so as to be orthogonal to the longitudinal directions (the central axis directions) of the multiple CCFLs 20 arranged in parallel with one another and installed on one end sides of the CCFLs 20. The second substrate 50 is divided into multiple regions corresponding to the CCFLs 20 to be connected, and each region constitutes the second block 2. Each second block B comprises four conductor layers. In Embodiment 1, a description will be made in the case of four conductor layers; however, when a capacitor is formed, it can be formed using two conductor layers between which a dielectric layer is held.

In the multilayer substrate with built-in capacitors according to Embodiment 1, the pattern shapes of the conductor layers in the second block B are common. Furthermore, in the second block B of the multilayer substrate with built-in capacitors according to Embodiment 1, the first conductor layer and the third conductor layer have similar pattern shapes, and the second conductor layer and the fourth conductor layer have similar pattern shapes.

The perspective view of FIG. 7 shows the first conductor layers (21A, 21B) and the fourth conductor layers (24A, 24B) provided for the second substrate 50. The first conductor layers (21A, 21B) are on the front face side (on the face side not opposed to the CCFL 20) of the second substrate 50, and the fourth conductor layers (24A, 24B) are on the back face side (on the face side opposed to the CCFL 20) of the second substrate 50.

The first conductor layer comprises two conductor layers 21A and 21B. The respective second blocks B provided for the second substrate 50 are mutually connected electrically using the respective first conductor layers 21A. A through hole 60 is formed in the second block B corresponding to the CCFL 20 located at one end of the array of the multiple CCFLs 20 disposed so as to be arranged on one plane. This through hole 60 is formed in the first conductor layer 21A of the second block B, and a metal film (copper thin film) serving as a conductor is formed on the inner face thereof. Hence, the metal film on the inner face of the through hole 60 serves as a surface electrode and is used as an input terminal common to all the second blocks B. A first lead wire 81 connected to the surface electrode of the through hole 60 is connected to the first block A (see FIG. 1) formed on the first substrate 40. The first lead wire 81 is soldered to the metal film inside the through hole 60, the metal film serving to form the surface electrode.

On the other hand, a second lead wire 82 for supplying power to the CCFL 20 is connected to the fourth conductor layer. The fourth conductor layer comprises two conductor layers 24A and 24B. A through hole 64 is formed in the second conductor layer 24B, and a metal film serving as a conductor is formed on the inner face of this through hole 64. Hence, the metal film inside the through hole 64 serves as a surface electrode. One end of the second lead wire 82 is soldered to the metal film inside the through hole 64, the metal film serving to form the surface electrode. In Embodiment 1, the through hole 64 serves as the output terminal of the second block B. The other end of the second lead wire 82 is connected to one electrode (the first electrode 20A) of the corresponding CCFL 20.

As described above, in the multilayer substrate with built-in capacitors according to Embodiment 1, the multiple ballast capacitors CB1, CB2 and CB3 formed in each second block B are connected in series, and the respective second blocks B are connected in parallel. Desired power is supplied to the CCFL 20 via the ballast capacitors CB1, CB2 and CB3 in each second block B.

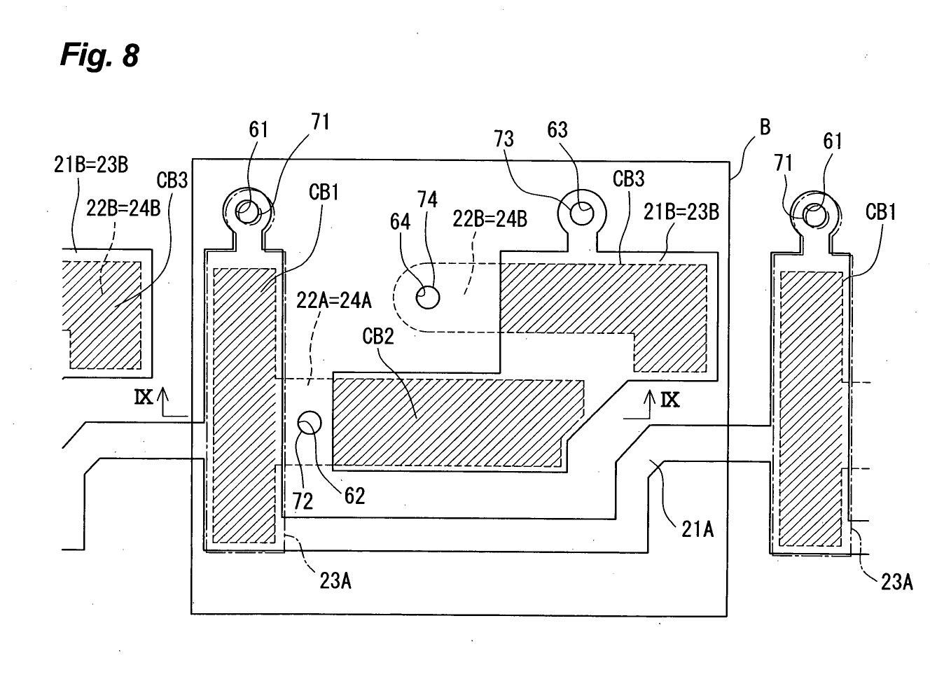

FIG. 8 is a view showing the patterns of the conductor layers constituting the second block B in the multilayer substrate with built-in capacitors according to Embodiment 1. FIG. 8 is a view seen from the front face side of the second substrate 50. The configuration of the second block B in the multilayer substrate with built-in capacitors according to Embodiment 1 is the configuration shown in (A) of FIG. 6 described above, and four conductor layers are used. These conductor layers are referred to as the first conductor layers (21A, 21B), the second conductor layers (22A, 22B), the third conductor layers (23A, 23B) and the fourth conductor layers (24A, 24B) in the order from the front face side (the face side not opposed to the CCFL 20, that is, the face side opposed to the side face of the case 10) of the second substrate 50.

In FIG. 8, the two conductor patterns 21A and 21B of the first conductor layer are indicated by solid lines, and the two conductor patterns 22A and 22B of the second conductor layer and the two conductor patterns 24A and 24B of the fourth conductor layer are indicated by broken lines. Furthermore, the conductor pattern 23A of the third conductor layer is indicated by a long and short dash line. The conductor pattern 23B of the third conductor layer is not shown because it has the same shape as that of the conductor pattern 21B of the first conductor layer.

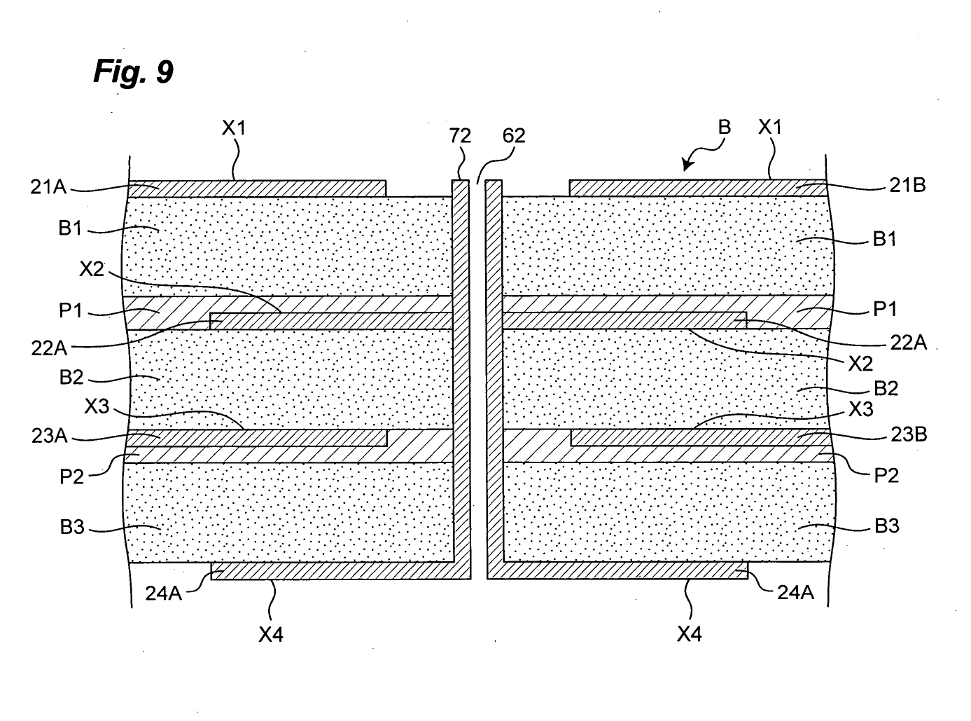

FIG. 9 is a sectional view showing a part of the second block B in the second substrate 50, cross-sectioned along line IX-IX of FIG. 8. The arrows along line IX-IX shown in FIG. 8 indicate the visual line direction in the sectional view of FIG. 9. In FIG. 9, the dimensions in the thickness direction (the vertical direction in FIG. 9) of the second substrate 50 are made larger than those in the longitudinal direction (the left-right direction in FIG. 9) thereof so that the following description is understood easily in a visual sense.

In FIG. 9, the first conductor layers (21A, 21B), the second conductor layer (22A), the third conductor layers (23A, 23B) and the fourth conductor layer (24A) are shown magnified in the order from the front face side (the upper side in FIG. 9) of the second substrate 50.

As shown in FIGS. 8 and 9, in the second block B, the two first conductor layers (21A, 21B) and the two third conductor layers (23A, 23B) have nearly similar patterns; in particular, the conductor pattern 21B of the first conductor layer and the conductor pattern 23B of the third conductor layer have the same shape. In other words, the conductor pattern 21B of the first conductor layer and the conductor pattern 23B of the third conductor layer are formed so as to be overlaid in a direction orthogonal to the surface of the second substrate 50. In addition, the conductor pattern 23A of the third conductor layer is formed so as to be overlapped with the conductor pattern 21A of the first conductor layer; however, the conductor pattern 21A of the first conductor layer has a connection part connected to the conductor pattern 21A of the first conductor layer of the adjacent second block B and thus differs from the conductor pattern 23A of the third conductor layer. This is because the conductor pattern 23A of the third conductor layer is separated from the conductor pattern 23A of the third conductor layer of the adjacent second block B and thus has no connection part.

As shown in FIG. 8, the conductor pattern 21A of the first conductor layer and the conductor pattern 23A of the third conductor layer are connected using the first connection part 71 formed on the inner face of the first through hole 61. The conductor pattern 21B of the first conductor layer and the conductor pattern 23B of the third conductor layer are connected using the third connection part 73 formed on the inner face of the third through hole 63.

Similarly, the two second conductor layers (22A, 22B) and the two fourth conductor layers (24A, 24B) have the same patterns, and the second conductor layers (22A, 22B) and the fourth conductor layers (24A, 24B) have the same shape and are disposed so as to be overlaid in a direction orthogonal to the surface of the second substrate 50. The conductor pattern 22A of the second conductor layer and the conductor pattern 24A of the fourth conductor layer are connected using the second connection part 72 formed on the inner face of the second through hole 62 (see FIG. 9). The conductor pattern 22B of the second conductor layer and the conductor pattern 24B of the fourth conductor layer are connected using the fourth connection part 74 formed on the inner face of the fourth through hole 64.

With respect to the connection states described above, refer to the schematic view of FIG. 6 described above, showing the first conductor layers (21A, 21B), the second conductor layers (22A, 22B), the third conductor layers (23A, 23B) and the fourth conductor layers (24A, 24B).

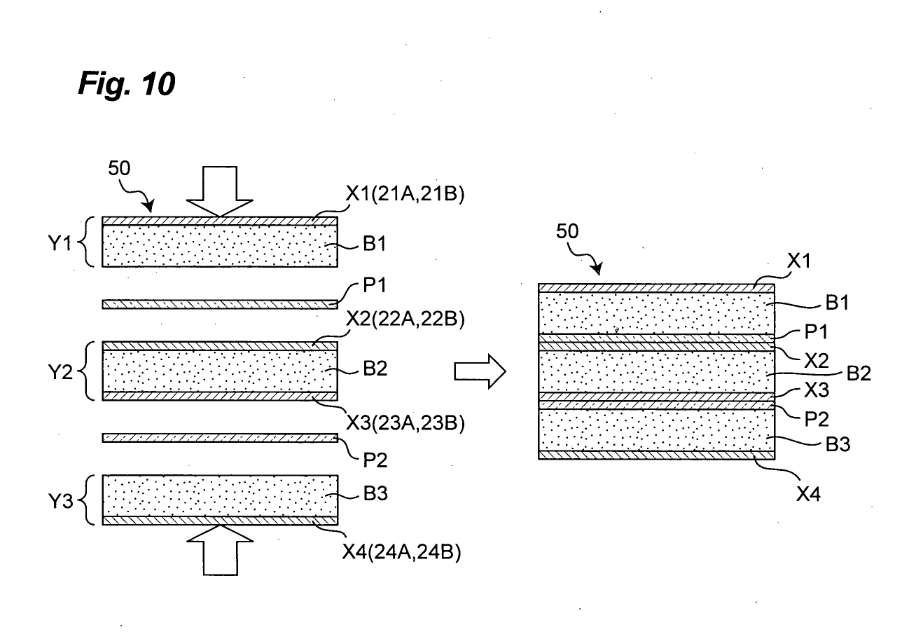

FIG. 10 is a structural sectional view showing a method for manufacturing the second block B in the second substrate 50. As shown in FIG. 10, the second substrate 50 is formed by disposing insulation layers made of dielectric members, such as three core members B1, B2 and B3, among the first conductor layers (21A, 21B), the second conductor layers (22A, 22B), the third conductor layers (23A, 23B) and the fourth conductor layers (24A, 24B) so as to be overlaid. The three core members B1, B2 and B3 according to Embodiment 1 are plates made of an epoxy resin containing glass fibers as a reinforcing material, for example, and preferably having a thickness in the range of 0.1 to 1.6 [mm].

In FIG. 10, a first conductor layer X1 disposed as the top layer has the pattern shapes of the first conductor layers (21A, 21B) described above, a second conductor layer X2 disposed as the second layer has the pattern shapes of the second conductor layers (22A, 22B), a third conductor layer X3 disposed as the third layer has the pattern shapes of the third conductor layers (23A, 23B), and a fourth conductor layer X4 disposed as the fourth layer has the pattern shapes of the fourth conductor layers (24A, 24B). The three core members B1, B2 and B3 being used in Embodiment 1 are uniform and have the same thickness.

The first conductor layer X1 is secured to the upper face of the first core member B1 to form a first member Y1. The second conductor layer X2 and the third conductor layer X3 are secured to the upper face and the lower face of the second core member B2, respectively, to form a second member Y2. In addition, the fourth conductor layer X3 is secured to the lower face of the third core member B3 to form a third member Y3. Each of the conductor layers X1, X2, X3 and X4 is a copper foil film having a thickness of 12 to 70 [μm], preferably 35 [μm], for example, and is formed by evaporation. Furthermore, the pattern shapes of the respective conductor layers X1, X2, X3 and X4 are preferably formed by etching.

Prepregs (molding intermediate materials made of a reinforcing material, such as carbon fibers, impregnated with a synthetic resin, such as an epoxy resin) P1 and P2 are respectively disposed among the first member Y1, the second member Y2 and the third member Y3, and bonded mutually. The thicknesses of the prepregs P1 and P2 are preferably in the range of 20 to 400 [μm], for example. Furthermore, the thicknesses of the prepregs P1 and P2 are preferably nearly equal.

In a method for manufacturing the multilayer substrate of the second substrate 50, for example, when mass production is carried out, as shown in FIG. 10, the first member Y1 that has the first conductor layer X1 having the predetermined conductor patterns (21A, 21B), the second member Y2 that has the second conductor layer X2 having the predetermined conductor patterns (22A, 22B) and the third conductor layer X3 having the predetermined conductor patterns (23A, 23B) on both faces thereof, and the third member Y3 that has the fourth conductor layer X4 having the predetermined conductor patterns (24A, 24B) are disposed so that the prepregs P1 and P2 are held among these, and then the whole is pressed vertically under heating, whereby the layers are press-bonded mutually. A multilayer substrate with built-in capacitors is thus produced by the press-bonding under heating as described above. At this time, the three core members B1, B2 and B3 having the conductor layers are pressed, thereby press-bonded so that no voids are formed inside.

In this production method, the prepreg resin is heated at a temperature-rising rate of 1 to 5° C./minute in its melting temperature range of 80 to 140° C., and then the temperature is held at 170 to 200° C. for 20 or more minutes to cure the prepreg resin. Press working is performed at an initial pressure of approximately 0.5 MPa for 5 to 10 minutes and then at 2.0 to 4 MPa.

As described above, in the production of the second substrate 50 according to Embodiment 1, a multiple substrate structure having a constant and stable interlayer thickness can be formed by simply applying pressure and by press-bonding the layers mutually at the predetermined temperature conditions. Furthermore, in the method for manufacturing the second substrate 50, void generation inside the prepregs P1 and P2 serving as bonding layers can be prevented securely because a method for press-bonding the whole is used.

Hence, with the method for manufacturing the multilayer substrate according to Embodiment 1, the capacitances among the respective conductor layers become nearly equal and uniform, whereby it is possible to produce a multilayer substrate with built-in capacitors, having high reliability easily and securely.

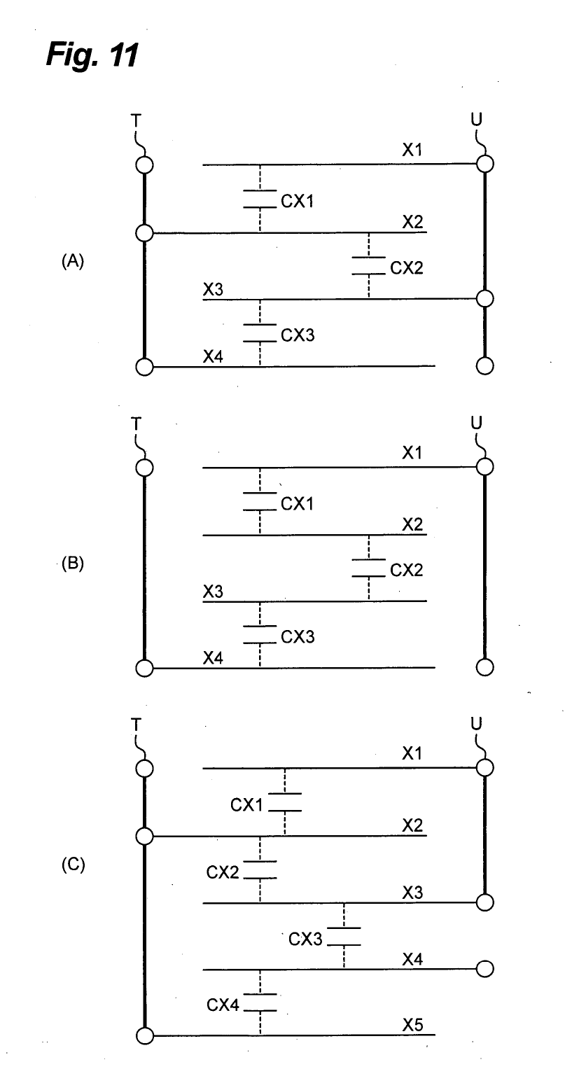

The interlayer capacitances of the multilayer substrate with built-in capacitors, that is produced using the production method described in Embodiment 1 will be described below referred to FIG. 11. FIG. 11 is a schematic view showing various structural examples of the multilayer substrate with built-in capacitors according to the present invention.

As described above, Embodiment 1 has a four-layer structure comprising the conductor layers X1, X2, X3 and X4, and the electrical connections among the respective conductor layers are made via the connection parts 71 to 74 inside the through holes 61 to 64 (see FIG. 8).

In FIG. 11, the connection parts inside the through holes are designated by letters T and U. (A) of FIG. 11 shows a case in which every other conductor layers of the four conductor layers are connected to a first connection part T and a second connection part U so as to form a comb shape. In other words, the first conductor layer X1 and the third conductor layer X3 are connected using the second connection part U, and the second conductor layer X2 and the fourth conductor layer X4 are connected using the first connection part T.

In the multilayer substrate with built-in capacitors shown in (B) of FIG. 11, the first conductor layer X1 serving as one of surface electrodes is connected to the second connection part U, and the fourth conductor layer X4 serving as the other surface electrode is connected to the first connection part T. Hence, in the multilayer substrate with built-in capacitors shown in (B) of FIG. 11, the second conductor layer X2 and the third conductor layer X3 are capacitance-coupled to the surface electrodes.

(C) of FIG. 11 shows a case in which five conductor layers are used. In the multilayer substrate with built-in capacitors shown in (C) of FIG. 11, the first conductor layer X1 and the third conductor layer X3 are connected using the second connection part U, and the second conductor layer X2 and a fifth conductor layer X5 are connected using the first connection part T.

In the structures shown in (A) to (C) of FIG. 11, the capacitor having the interlayer capacitance between the first conductor layer X1 and the second conductor layer X2 is referred to as a ballast capacitor CX1, the capacitor having the interlayer capacitance between the second conductor layer X2 and the third conductor layer X3 is referred to as a ballast capacitor CX2, and the capacitor having the interlayer capacitance between the third conductor layer X3 and the fourth conductor layer X4 is referred to as a ballast capacitor CX3. In addition, in (C) of FIG. 11, the capacitor having the interlayer capacitance between the fourth conductor layer X4 and the fifth conductor layer X5 is referred to as a ballast capacitor CX4. In FIG. 11, interlayer capacitances other than those shown as the ballast capacitors CX1, CX2, CX3 and CX4 are present in reality at the overlapping parts of the respective conductor layers; however, the following description is given using the ballast capacitors CX1, CX2, CX3 and CX4 shown in FIG. 11 for the sake of simplifying description.

In the structure of the multilayer substrate with built-in capacitors shown in (A) of FIG. 11, since the conductor layers are connected in a comb shape, the ballast capacitors CX1, CX2 and CX3 formed among the respective layers are connected in parallel, whereby the capacitance value can be set large.

In the structure of the multilayer substrate with built-in capacitors shown in (B) of FIG. 11, since the second conductor layer X2 and the third conductor layer X3, not connected to the connection parts T and U, have a capacitance-coupled structure, the ballast capacitors CX1, CX2 and CX3 are connected in series, whereby the withstand voltage of the whole capacitor can be improved.

In the structure of the multilayer substrate with built-in capacitors shown in (C) of FIG. 11, five conductor layers are used, the ballast capacitors CX1 and CX2 are connected in parallel, and the ballast capacitors CX3 and CX4 are connected in series. In addition, their respective combined capacitances are further connected in parallel. Hence, in the multilayer substrate with built-in capacitors shown in (C) of FIG. 11, the capacitance value can be set large, and the withstand voltage of the whole capacitor can be improved. Furthermore, in the structure of the multilayer substrate with built-in capacitors shown in (C) of FIG. 11, the fourth conductor layer X4 serving as the conductor layer common to the ballast capacitors CX3 and CX4 can also be connected to the first conductor layer X1 serving as the surface electrode via the second connection part U.

In the multilayer substrate with built-in capacitors according to the present invention, more ballast capacitors can also be formed by forming more than five conductor layers. By this formation of multiple conductor layers, the desired capacitor capacitance value and withstand voltage required for the multilayer substrate with built-in capacitors can be obtained securely.

Next, in the CCFL lighting device according to Embodiment 1 of the present invention, the multilayer substrate with built-in capacitors configured as described above will be described specifically.

The multilayer substrate with built-in capacitors for use in the CCFL lighting device according to Embodiment 1 has multiple conductor patterns that are formed by electrically separating the respective conductor layers as described above, and the overlapping parts of these conductor patterns are used as ballast capacitors. The multilayer substrate with built-in capacitors according to Embodiment 1 configured by connecting the multiple capacitors configured as described above will be described further specifically.

As shown in FIGS. 8 and 9 described above, the multiple conductor patterns (21A and 21B, 22A and 22B, 23A and 23B and 24A and 24B) mutually separated electrically are formed in the respective conductor layers X1, X2, X3 and X4. In other words, the conductor patterns (21A and 21B) are formed in the first conductor layer X1, the conductor patterns (22A and 22B) are formed in the second conductor layer X2, the conductor patterns (23A and 23B) are formed in the third conductor layer X3, and the conductor patterns (24A and 24B) are formed in the fourth conductor layer X4. As described above, the conductor patterns formed in the first conductor layer X1 and the third conductor layer X3 have nearly the same conductor pattern except for the conductor part of the connection part connected to the adjacent ballast capacitor. In addition, the conductor patterns formed in the second conductor layer X2 and the fourth conductor layer X4 have the same pattern. In other words, the conductor pattern (21A) of the first conductor layer X1 is nearly the same as the conductor pattern (23A) of the third conductor layer X3 except for the connection part connected to the adjacent ballast capacitor. Furthermore, the conductor pattern (21B) of the first conductor layer X1 and the conductor pattern (23B) of the third conductor layer X3 have the same shape, the conductor pattern (22A) of the second conductor layer X2 and the conductor pattern (24A) of the fourth conductor layer X4 have the same shape, and the conductor pattern (22B) of the second conductor layer X2 and the conductor pattern (24B) of the fourth conductor layer X4 have the same shape. The conductor layers X1, X2, X3 and X4 are connected so as to form the so-called comb structure, and the overlapping parts of the above-mentioned conductor patterns form the ballast capacitors CB1, CB2 and CB3. In the configuration according to Embodiment 1, the ballast capacitors CB1, CB2 and CB3 are connected in series, and one end thereof is connected to the CCFL (cold-cathode tube) 20.

In the second block B connected to the CCFL 20 shown in FIG. 8, in the regions in which the conductor patterns 21A, 22A, 23A and 24A in the first to fourth conductor layers X1, X2, X3 and X4 are overlapped, the first ballast capacitor CB1 in which the interlayer capacitances among them are combined is formed. For example, in FIG. 8, the overlapping regions are indicated using slanting lines, and the slanted region designated by CB1 nearly becomes the region in which the first ballast capacitor CB1 is formed. The first ballast capacitor CB1 is substantially equal to the parallel connection of mainly three interlayer capacitances, that is, the interlayer capacitance between the conductor pattern (21A) of the first conductor layer X1 and the conductor pattern (22A) of the second conductor layer X2, the interlayer capacitance between the conductor pattern (22A) of the second conductor layer X2 and the conductor pattern (23A) of the third conductor layer X3, and the interlayer capacitance between the conductor pattern (23A) of the third conductor layer X3 and the conductor pattern (24A) of the fourth conductor layer X4.

Similarly, the second ballast capacitor CB2 has the combined capacitance of the interlayer capacitance between the conductor pattern (21B) of the first conductor layer X1 and the conductor pattern (22A) of the second conductor layer X2, the interlayer capacitance between the conductor pattern (22A) of the second conductor layer X2 and the conductor pattern (23B) of the third conductor layer X3, and the interlayer capacitance between the conductor pattern (23B) of the third conductor layer X3 and the conductor pattern (24A) of the fourth conductor layer X. For example, the slanted region designated by CB2 in FIG. 8 nearly becomes the region in which the second ballast capacitor CB2 is formed.

Furthermore, the third ballast capacitor CB3 has the combined capacitance of the interlayer capacitance between the conductor pattern (21B) of the first conductor layer X1 and the conductor pattern (22B) of the second conductor layer X2, the interlayer capacitance between the conductor pattern (22B) of the second conductor layer X2 and the conductor pattern (23B) of the third conductor layer X3, and the interlayer capacitance between the conductor pattern (23B) of the third conductor layer X3 and the conductor pattern (24B) of the fourth conductor layer X4. For example, the slanted region designated by CB3 in FIG. 8 nearly becomes the region in which the third ballast capacitor CB3 is formed.

As described above, in the multilayer substrate with built-in capacitors for use in the CCFL lighting device according to Embodiment 1, the three ballast capacitors CB1, CB2 and CB3 are connected in the so-called comb shape to form a capacitor.

Each capacitance of the ballast capacitors CB1, CB2 and CB3 in the multilayer substrate with built-in capacitors according to Embodiment 1 is approximately several [pF]. This capacitance is adjustable by appropriately adjusting the overlapping areas of the conductor patterns, the thicknesses of the core members B1, B2 and B3 and the thicknesses of the prepregs P1 and P2, for example. In addition, in the capacitances of the capacitors in the multilayer substrate with built-in capacitors, the capacitance of each ballast capacitor can be changed significantly by increasing the number of layers in the structure of the layers overlaid.

In the second block B of the second substrate 50 in the CCFL lighting device according to Embodiment 1, the conductor pattern (21A) of the first conductor layer X1 and the conductor pattern (23A) of the third conductor layer X3, constituting one end side of the first ballast capacitor CB1, are connected to the first block A on the power source side. On the other hand, in the second block B, the conductor pattern (22B) of the second conductor layer X2 and the conductor pattern (24B) of the fourth conductor layer X4, constituting one end side of the third ballast capacitor CB3, are connected to the electrode 20A serving as one of the electrodes of the CCFL 20.

In the second substrate 50 in the CCFL lighting device according to Embodiment 1, the stray capacitance between a conductor layer and the outside of the device (for example, the case 10) is smaller as the conductor layer is farther away from the side face of the case 10. In other words, in Embodiment 1, the stray capacitance between the fourth conductor layer X4 and the outside of the device is smallest and almost negligible. Hence, in the configuration according to Embodiment 1 wherein the fourth conductor layer X4 in the second block B of the second substrate 50 is connected to the first electrode 20A of the CCFL 20, the potential of the first electrode 20A is less affected by the stray capacitance between the conductor layer and the outside of the device.

On the other hand, the output of the first block A for supplying power to the second block B is stable, regardless of the magnitude of the stray capacitance between the conductor layer in the second block B and the outside of the device. Hence, in the configuration of the CCFL lighting device according to Embodiment 1, since the potential of the first electrode 20A hardly varies among the multiple CCFLs 20, the uniformity of the tube current, namely, the uniformity of luminance, is improved.

In the configuration of the CCFL lighting device according to Embodiment 1, in the third block C connected to the second electrode 20B of each CCFL 20, a connection part for connecting the second electrode 20B of the CCFL 20 to the ground is formed (see FIG. 3). For example, the conductor layer formed inside the third substrate 60 is used to connect the second electrode 20B of the CCFL 20 to the grounding conductor outside the device. As described above, the second electrode 20B of each CCFL 20 is grounded via the third block C.

Furthermore, in the configuration of the CCFL lighting device according to Embodiment 1, the second block B that is connected to the first electrode 20A of each CCFL 20 is connected to one terminal of the secondary winding 52 of the step-up transformer 5 as shown in FIG. 3. The other terminal of the secondary winding 52 is grounded.

Various stray capacitances are present (not shown) in the periphery of the CCFL 20. The stray capacitances include the stray capacitance SC (see FIG. 2) between the CCFL 20 and the case 10, and the stray capacitances of the wires for connecting the first block A, the second block B, the CCFL 20, the third block C and the grounding conductor, for example. Hence, the stray capacitances in the periphery of the CCFL 20 are different for each CCFL 20. The total of the stray capacitances is approximately several [pF], for example.

In the configuration of the CCFL 20 according to Embodiment 1, the total capacitance of the ballast capacitors CB1, CB2 and CB3 is adjusted for each second block B. In other words, the total capacitance is adjusted for each of the multiple CCFLs 20 arranged in parallel. For example, by increasing the areas of the overlapping regions of the conductor patterns (21A, 22A, 23A and 24A) in the first to fourth conductor layers X1, X2, X3 and X4, the capacitance of the ballast capacitor CB1 can be increased. The capacitances of the ballast capacitors CB1, CB2 and CB3 indicated using slanting lines in FIG. 8 are adjusted in consideration of the installation conditions (for example, wire length, the shape of conductor pattern, the distance between the tube wall of the CCFL 20 and the case 10, the distance between the respective CCFLs 20, etc.) between the ballast capacitors and the corresponding CCFL 20.

For example, among the multiple CCFLs 20 arranged in parallel, in the CCFL 20 nearest the side face of the case 10, the stray capacitance SC between the tube wall and the side face of the case 10 is large. Hence, the total capacitance of the ballast capacitors CB1, CB2 and CB3 connected to the CCFL 20 is set large.

As described above, in the configuration of the CCFL lighting device according to Embodiment 1, the capacitance is adjusted for each combination of each CCFL 20 and the second block 2, and the total capacitance of the ballast capacitors CB1, CB2 and CB3 substantially coincides with the stray capacitances in the periphery of the CCFL 20. In other words, the total impedance of the ballast capacitors CB1, CB2 and CB3 is matched with the combined impedance of the stray capacitances in the periphery of the CCFL 20.

In the configuration of the CCFL lighting device according to Embodiment 1, since the first block A is low in output impedance, the impedance matching described above is attained easily.

Preferably, the total impedance of the ballast capacitors CB1, CB2 and CB3 is set so as to be matched with the impedance of each CCFL 20 during lighting.

In the CCFL lighting device according to Embodiment 1 of the present invention, the output impedance of the step-up transformer 5 is suppressed as described above, contrary to the presumption in the conventional CCFL lighting device. Instead, the series connection of the ballast capacitors CB1, CB2 and B3 is connected as one set to each CCFL 20. The method for connecting the ballast capacitors CB1, CB2 and CB3 is selected in consideration of the capacitance value and the withstand voltage that the capacitor to be connected to the CCFL should have, and the connection may be a parallel connection or a mixed connection of series and parallel connections, for example.

In the CCFL lighting device according to Embodiment 1 of the present invention, in particular, the impedances of the connections to be connected to the CCFLs 20 are set separately so as to cancel the differences in the peripheral stray capacitances among the multiple CCFLs 20. Hence, no variation occurs in tube current among the multiple CCFLs 20, and uniform luminance is maintained in the respective CCFLs 20.

As described above, the CCFL lighting device according to Embodiment 1 of the present invention can uniformly light the multiple CCFLs 20 using the common low-impedance power source (the first block A). In addition, the CCFL lighting device according to Embodiment 1 has a configuration capable of dealing with long wires among the first block A, the second block B and the third block C. Furthermore, in the CCFL lighting device according to Embodiment 1, even if the capacitance is different significantly in the respective CCFLs 20, the difference can be adjusted using the ballast capacitors CB1, CB2 and CB3, whereby the layout of the wiring is high in flexibility. Hence, the CCFL lighting device according to Embodiment 1 of the present invention is a highly versatile device, the total size of which can be downsized easily.

Furthermore, in the CCFL lighting device according to Embodiment 1 of the present invention, the ballast capacitors CB1, CB2 and CB3 are each formed by combining the capacitances among the conductor layers inside the second substrate 50. With this configuration of the CCFL lighting device according to Embodiment 1, the ballast capacitors CB1 to CB3 can be wholly embedded inside the second substrate 50. As a result, the distance between the CCFL 20 and the surface of the second substrate 50 can be shortened extremely, thereby greatly contributing to the downsizing of the device.

As being clarified in the description of the CCFL lighting device according to Embodiment 1 described above, in the CCFL lighting device according to the present invention, the use of the ballast capacitors CB1, CB2 and CB3 is extremely effective in thinning electrical apparatuses, such as liquid crystal displays; furthermore, since the second substrate 50 can be produced easily by using core members having an almost uniform thickness and by press-bonding them, multilayer substrates with built-in capacitors, having a uniform capacitance and high reliability can be mass-produced easily and securely.

### INDUSTRIAL APPLICABILITY

The present invention is useful in a cold-cathode tube lighting device for lighting cold-cathode tubes serving as light sources.

1. A multilayer substrate with built-in capacitors having at least four conductor layers overlaid via dielectric layers, comprising at least:
a first member on which a first conductor layer having a predetermined conductor pattern is overlaid on one face of a first dielectric layer,
a second member having a second conductor layer and a third conductor layer each having a predetermined conductor pattern and overlaid on both faces of a second dielectric layer, respectively,
a third member having a fourth conductor layer having a predetermined conductor pattern and overlaid on one face of a third dielectric layer,
a first bonding layer disposed between the other face of said first dielectric layer and one face of said second member so as to bond the faces mutually, and
a second bonding layer disposed between the other face of said third dielectric layer and the other face of said second member so as to bond the faces mutually, wherein
specific conductor patterns are connected using the connection parts of through holes formed at predetermined positions in said multilayer substrate with built-in capacitors, thereby forming multiple capacitor blocks among said conductor layers.

2. The multilayer substrate with built-in capacitors according to claim 1, wherein said multiple blocks are connected in series using said conductor patterns via said connection parts of said through holes.

3. The multilayer substrate with built-in capacitors according to claim 1, wherein said multiple blocks are connected in parallel using said conductor patterns via said connection parts of said through holes.

4. The multilayer substrate with built-in capacitors according to claim 1, wherein said conductor patterns of every other layers overlaid in said blocks have substantially the same shape.

5. The multilayer substrate with built-in capacitors according to claim 1, wherein said conductor patterns of every other layers overlaid in said blocks have substantially same shape, specific conductor patterns of every other layers are connected using said connection parts of through holes so as to form a comb structure, and multiple interlayer capacitances are connected in series.

6. The multilayer substrate with built-in capacitors according to claim 1, wherein said respective bonding layers are made of an epoxy-based synthetic resin containing a reinforcing material formed of carbon fibers.

7. The multilayer substrate with built-in capacitors according to claim 1, wherein said respective dielectric layers are formed of an epoxy resin substrate containing glass fibers as a reinforcing material.

8. The multilayer substrate with built-in capacitors according to claim 1, being used for a lighting device having multiple cold-cathode tubes arranged in parallel, and disposed so as to be orthogonal to the central axes of said cold-cathode tubes.

9. A method for manufacturing a multilayer substrate with built-in capacitors having at least four conductor layers overlaid via dielectric layers, comprising at least:
a step of producing a first member on which a first conductor layer having a predetermined conductor pattern is overlaid on one face of a first dielectric layer,
a step of producing a second member having a second conductor layer and a third conductor layer each having a predetermined conductor pattern and overlaid on both faces of a second dielectric layer, respectively,
a step of producing a third member having a fourth conductor layer having a predetermined conductor pattern and overlaid on one face of a third dielectric layer,
a step of disposing a first bonding layer between the other face of said first dielectric layer and one face of said second member,
a step of disposing a second bonding layer between the other face of said third dielectric layer and the other face of said second member,
a step of carrying out heating and pressing in a direction of sandwiching said first dielectric layer, said second dielectric layer and said third dielectric layer via said first bonding layer and said second bonding layer so as to bond said layers mutually,
a step of forming through holes at predetermined positions of specific conductor patterns, and
a step of forming multiple capacitor blocks among said conductor layers by forming connection parts on the inner faces of said through holes and by electrically connecting specific conductor patterns.

10. The method for manufacturing a multilayer substrate with built-in capacitors according to claim 9, wherein said multiple blocks are connected in series using said conductor patterns via said connection parts of said through holes.

11. The method for manufacturing a multilayer substrate with built-in capacitors according to claim 9, wherein said multiple blocks are connected in parallel using said conductor patterns via said connection parts of said through holes.

12. The method for manufacturing a multilayer substrate with built-in capacitors according to claim 9, wherein said conductor patterns of every other layers overlaid in said blocks have substantially the same shape.

13. The method for manufacturing a multilayer substrate with built-in capacitors according to claim 9, wherein said conductor layers are formed by evaporation of metal thin films.

14. The method for manufacturing a multilayer substrate with built-in capacitors according to claim 9, wherein said respective bonding layers are made of an epoxy-based synthetic resin containing a reinforcing material formed of carbon fibers.

15. The method for manufacturing a multilayer substrate with built-in capacitors according to claim 14, wherein said respective dielectric layers are formed of an epoxy resin substrate containing glass fibers as a reinforcing material.

16. A cold-cathode lighting device equipped with:
a multilayer substrate with built-in capacitors, having multiple ballast capacitors formed of at least four conductor layers overlaid via dielectric layers, and
a low-impedance power source, having a low output impedance, for supplying power to cold-cathode tube via said ballast capacitors,
said multilayer substrate with built-in capacitors, having at least four conductor layers overlaid via dielectric layers, comprising at least:
a first member on which a first conductor layer having a predetermined conductor pattern is overlaid on one face of a first dielectric layer,
a second member having a second conductor layer and a third conductor layer each having a predetermined conductor pattern and overlaid on both faces of a second dielectric layer, respectively,
a third member having a fourth conductor layer having a predetermined conductor pattern and overlaid on one face of a third dielectric layer,
a first bonding layer disposed between the other face of said first dielectric layer and one face of said second member so as to bond the faces mutually, and
a second bonding layer disposed between the other face of said third dielectric layer and the other face of said second member so as to bond the faces mutually, wherein
specific conductor patterns are connected using the connection parts of through holes formed at predetermined positions in said multilayer substrate with built-in capacitors, thereby forming multiple capacitor blocks among said conductor layers.

17. The cold-cathode lighting device according to claim 16, equipped with said multilayer substrate with built-in capacitors, wherein said multiple blocks are connected in series using said conductor patterns via said connection parts of said through holes.

18. The cold-cathode lighting device according to claim 16, equipped with said multilayer substrate with built-in capacitors, wherein said multiple blocks are connected in parallel using said conductor patterns via said connection parts of said through holes.

19. The cold-cathode lighting device according to claim 16, equipped with said multilayer substrate with built-in capacitors, wherein said conductor patterns of every other layers overlaid in said blocks have substantially the same shape.

20. The cold-cathode tube lighting device according to claim 16, wherein said low-impedance power source is mounted on a substrate different from said multilayer substrate with built-in capacitors.

21. The cold-cathode tube lighting device according to claim 16, having multiple cold-cathode tubes arranged in parallel, said multilayer substrate with built-in capacitors being disposed so as to be orthogonal to the central axes of said cold-cathode tubes, wherein a power source circuit for said respective cold-cathode tubes is provided in a different region.

22. The cold-cathode tube lighting device according to claim 16, wherein, among said multiple conductor layers in said multilayer substrate with built-in capacitors, the conductor layer nearest said cold-cathode tube is connected to the electrode of said cold-cathode tube, and the conductor layer farthest from said cold-cathode tube is connected to said low-impedance power source.

23. The cold-cathode tube lighting device according to claim 16, wherein said low-impedance power source includes a transformer, and said transformer comprises a core, a primary winding wound around said core and a secondary winding wound around the inside or outside or both the inside and outside of said primary winding.

24. The cold-cathode tube lighting device according to claim 16, wherein said low-impedance power source is configured so as to have a power transistor.
